(19) United States
(12) Patent Application Publication
(10) Pub. No.: US 2023/0075393 A1
(43) Pub. Date: Mar. 9, 2023

(54) APPARATUS, SYSTEMS AND METHODS FOR LOAD-ADAPTIVE 3D WIRELESS CHARGING

(71) Applicant: GaN Systems Inc., Kanata (CA)

(72) Inventors: Tiefeng SHI, San Jose, CA (US); Paul WIENER, Pleasanton, CA (US)

(21) Appl. No.: 17/800,316

(22) PCT Filed: Feb. 5, 2021
(86) PCT No.: PCT/CA2021/050127

§ 371 Date: Aug. 17, 2022

Related U.S. Application Data
(60) Provisional application No. 62/977,783, filed on Feb. 18, 2020.

(51) Int. Cl. H02J 50/12; H02J 50/00; H02J 50/90; H02J 50/80; H02J 7/00; H01F 27/28

(52) U.S. Cl. CPC H02J 50/12; H02J 50/005; H02J 50/90; H02J 50/80; H02J 7/00308; H02J 7/00304; H01F 27/2804; H03F 3/2176

(57) ABSTRACT

Apparatus, systems and methods for load-adaptive 3D wireless charging are disclosed. In a 3D charging system of an example embodiment, features comprise a 3D coil design that provides magnetic field distribution coverage for a 3D charging space, e.g.

hemi-spherical space/volume; a push-pull class EF2 PA with EMI filter and transmitter circuitry that provides constant current to the 3D coil, with current direction, phase and timing control capability to adapt to load conditions; reactance shift detection circuitry comprising a voltage sensor, current sensor and phase detector and hardware for fast, real-time, computation of reactance and comparison to upper and lower limits for load-adaptive reactance tuning and for auto-protection; and a switchable tuning capacitor network arrangement of shunt and series capacitors configured for auto-tuning of input impedance, e.g. in response to a X detection trigger signal, which enables both coarse-tuning and uniform fine-tuning steps over an extended reactance range.

### CROSS-REFERENCE TO RELATED APPLICATION(S)

This application claims priority from U.S. provisional patent application No. 62/977,783, filed Feb. 18, 2020, entitled “Apparatus, Systems and Methods for Load-Adaptive 3D Wireless Charging” which is incorporated herein by reference in its entirety.

This application is related to U.S. patent application Ser. No. 17/094,061 filed Nov. 10, 2020, entitled “High Efficiency Resonator Coils for Large Gap Wireless Power Transfer Systems”, which claims the benefit of U.S. provisional patent application No. 62/947,144, filed Dec. 12, 2019, entitled “High Efficiency Resonator Coils for Large Gap Wireless Power Transfer Systems”, which are incorporated herein by reference in their entirety.

### TECHNICAL FIELD

Inventions disclosed herein relate to wireless power transfer (WPT), e.g. apparatus, systems, and methods and apparatus to accomplish WPT, and more particularly relate to three-dimensional (3D) wireless charging of mobile devices based on resonant inductive power transfer.

### BACKGROUND

Electromagnetic resonance power transfer, which may be referred to as resonant inductive wireless power transfer (WPT) or resonant inductive wireless energy transfer, works by creating a wireless transfer of electrical energy between two coils, tuned to resonate at the same frequency. Based on the principles of electromagnetic coupling, resonant-based power sources inject an oscillating current into a highly resonant coil to create an oscillating electromagnetic field. A second coil with the same resonant frequency receives power from the electromagnetic field and converts it back into an electrical current that can be used to power and charge devices.

For example, Standard IEC 63028:2017(E) defines technical requirements, behaviors and interfaces used for ensuring interoperability for flexibly coupled WPT systems for the AirFuel Alliance Resonant WPT. Resonant inductive energy transfer enables transmission of energy over longer distances than non-resonant inductive charging (see Table 1 below). For example, Wireless Power Consortium (WPC), formerly Qi, relates to (non-resonant) inductive WPT, which has a limited range, e.g. a few mm. AirFuel Alliance was formerly PMA, AW4P and Rezence. AirFuel resonant inductive WPT has a larger range, e.g. a maximum range of 50 mm. For example, AirFuel compliant resonant inductive WPT allows for a gap of up to 50mm between the transmitter coil and receiver coil, and provides for charging of multiple devices.

TABLE 1

| | Wireless Power | AirFuel Alliance |
|---|---|---|
| Standard Organization | Consortium (Qi) | (Rezence) |
| Method | Inductive | Resonant |
| Frequency Range | 80 kHz to 300 kHz | 6.78 MHz |
| Maximum transfer range | 5 mm | 50 mm |
| Number of charging devices | One | One and Multiple |
| Communications system | Load modulation | Bluetooth |

At present, commercially available technology for wireless charging of small mobile communication devices, e.g. smartphones, tablets, watches and other wearable devices, is typically based on a charging unit comprising a planar charging surface, e.g. a pad or a tray (e.g. see examples in FIG. 5). The charging pad contains a power source and a transmitter coil, and the mobile device contains a receiver coil. For inductive WPT, the mobile device is placed directly on the charging pad for charging, so it may be difficult or inconvenient to make use of the mobile device during charging.

Charging stations are now being developed for 3D wireless charging of mobile devices. 3D wireless charging offers more spatial freedom and a larger gap between the charging station and the mobile device, potentially enabling a user to continue using a mobile device while it is charging. However, 3D charging of multiple devices adds significant design complexity: for example, there are design challenges relating to providing coil designs for generating 3D magnetic fields over a required charging space (i.e. volume or region); detection of the placement (or removal) and positioning (orientation) of one or more devices at a charging station; and load-dependent impedance detection and impedance matching to maintain efficient operation of the power amplifier (PA) of the transmitter.

To achieve optimum system efficiency, the effective load seen by the PA, e.g. input impedance Zᵢₙ, is tuned to a range in which the PA operates at highest efficiency, e.g. as described in the above-referenced related U.S. patent application No. 62/947,144. For example, a switch mode class EF2 power amplifier offers high efficiency, EMI performance and compact topology (see article entitled “High Power Constant Current Class EF2 GaN Power Amplifier for AirFuel Magnetic Resonance Wireless Power Transfer Systems”, by Tiefeng Shi and Paul Wiener, PCIM, 5-7 Jun. 2018).

For low power applications of WPT, in which the variation of input impedance is small, many systems work without tuning or use a simple auto-tuning system. For higher power applications, or more complex WPT systems, such as 3D charging, where there may be large variations of input impedance, a load dependent auto-tuning system is needed for system reliability and efficiency. For 3D charging applications of multiple devices, the input impedance may vary significantly, and may vary over a wider range of impedance, e.g. dependent on the number of devices and the positioning of devices placed at a charging station. Thus 3D charging systems require some form of impedance detection and impedance tuning for system reliability: e.g. to limit over-current or over-voltage conditions and thermal overload of the PA, which may arise from a load which is too inductive or too capacitative, and to maintain a safe operating temperature, e.g. to operate the charging station in a high efficiency range to limit unwanted thermal dissipation.

There is a need for improved or alternative apparatus, systems and methods for 3D wireless charging, which address at least one of the above-mentioned issues.

### SUMMARY OF INVENTION

Inventions disclosed herein seek to provide apparatus, systems and methods for 3D wireless charging, which mitigate or circumvent at least one of the above-mentioned issues, or at least provide an alternative.

Aspects of the inventions disclosed herein comprise apparatus, systems and methods for load-adaptive 3D wireless charging. In a 3D charging system of an example embodiment, features comprise a 3D coil design that provides magnetic field distribution coverage for a 3D charging space, e.g. hemi-spherical space/volume; a push-pull class EF2 PA with EMI filter and transmitter circuitry that provides constant current to the 3D coil, with current direction, phase and timing control capability to adapt to load conditions; reactance-shift detection circuitry comprising a voltage sensor, current sensor and phase detector and hardware for fast, real-time, computation of reactance and comparison to upper and lower limits for load-adaptive reactance tuning and for auto-protection; and a switchable tuning capacitor network arrangement of shunt and series capacitors configured for auto-tuning of input impedance, e.g. in response to a reactance-shift (X-shift) detection trigger signal, which enables both coarse-tuning and uniform fine-tuning steps over an extended reactance range.

One aspect provides a resonator coil for generating a magnetic field distribution for a transmitter of an inductive wireless power transfer (WPT) system, comprising: conductive traces patterned to define a coil topology comprising a plurality of turns, having first and second feed ports; each turn comprising a first part wherein said conductive traces are defined in a first plane, and a second part wherein said conductive traces are defined in a second plane, turns of the first and second parts being serially interconnected.

The first plane may be orthogonal to the second plane. For example, the resonator coil comprises a coil topology is configured to generate a three-dimensional (3D) magnetic field distribution for wireless charging within a 3D charging space, e.g. the coil topology is configured to generate a three-dimensional magnetic field distribution for wireless charging within a hemi-spherical charging space. For example, the first plane comprises an xy plane, and the second plane comprises a xz plane. For example, where the first plane comprises an xy plane, and the second plane comprises a xz plane, the charging space comprises a first half and a second half (or in reference to a spherical shape with four quadrants, first and second quadrants) on opposite sides (i.e. −y and +y sides) of the xz plane.

Trace widths and trace spacings of each turn of the coil may be configured to optimize a uniformity of the magnetic field distribution within the charging space.

The Tx resonator may be fabricated based on PCB technology, e.g. comprising a dielectric substrate having a first part that extends in the first plane and a second part that extends in the second plane; and wherein said first parts of the conductive traces are supported by the first part of the dielectric substrate and the said second parts of the conductive traces are supported by the second part of the dielectric substrate.

For example, the power amplifier (PA) of the 3D resonant inductive wireless charging system may comprise a Class E or Class EF2 amplifier comprising a push-pull topology, or a single-ended topology, for driving the 3D coil.

Another aspect comprises a system for controlling current direction in 3D coil, dependent on load, using a push pull PA configuration. For example, a 3D resonant wireless charging system comprises a 3D resonator coil, as described herein, and a push-pull Class E

PA or class EF2 PA, and a control system configured to enable control of current direction supplied to the resonator coil responsive to a load condition.

A 3D resonant wireless charging system may comprise a resonator coil having a coil topology configured to generate a three-dimensional (3D) magnetic field distribution for wireless charging within a 3D charging space, and a single ended or push-pull Class E PA or a class EF2 PA, and a control system. For a push-pull PA, the control system may be configured to enable control of a time interval and/or a phase of current flow on each part of the coil responsive to said load condition.

Also disclosed is a receiver coil (gauge coil or reference coil) for use with a calibration unit of a 3D resonant inductive charging system, the receiver coil comprising at least two orthogonal coils, and preferably 3 orthogonal coils, for characterizing a 3D magnetic field distribution of a 3D charging space.

Also disclosed is a receiver coil for resonant inductive charging of a mobile device, the receiver coil being non-planar and symmetric about a z axis.

Another aspect provides a reactance-shift (X-shift) detection circuit for a 3D resonant inductive wireless charging system comprising:
electronic circuitry (i.e. a hardware implementation as logic circuitry) comprising:
a first input for receiving a first signal from a voltage sensor,
a second input for receiving a second signal from a current sensor, and
a third input for receiving a third signal from a phase detector;
a first output for outputting a low reactance trigger signal; and
a second output for outputting a high reactance trigger signal;
the electronic circuitry being configured for processing said first, second and third signals to provide a real-time computation of a computed reactance value; and comprising comparator circuitry for comparing said computed reactance value to stored reference values comprising an upper value of a reactance window and lower value of a reactance window; and if the said reactance value is greater than the upper value, generating and outputting a high reactance trigger signal; and
if the said reactance value is less than the lower value, generating and outputting a low reactance trigger signal.

For example, the upper value of the reactance window and lower value of the reactance window are selected to generate trigger signals for auto-tuning of reactance, and/or to generate trigger signals to implement over-voltage and over-current protection.

By way of example, the reactance shift detection circuitry may be implemented in hardware, comprising a phase detection circuit; a current sensing circuit; and a voltage sensing circuit; and logic circuitry for combining inputs from the current sensor, voltage sensor and phased sensor, to provide output trigger signals based on obtaining an output based on a hardware implementation to compute a threshold voltage based on VSENSE*(VPHASE-VPHASE0)/ISENSE, as described in detail herein.

Another aspect provides a circuit for load-adaptive auto-tuning of a power transmitter of a resonant inductive power transfer system, the circuit comprising a tuning capacitor arrangement connected between an input for receiving current from a power amplifier and an output for driving a Tx resonator coil, the capacitor arrangement comprising:
a first series tuning capacitor;
a plurality of switchably connected parallel (shunt) capacitors connected in parallel with the first series tuning capacitor, each of said plurality of switchably connected parallel capacitors having a series connected switch; and
a plurality of series capacitors that are switchably connected in series, each series capacitor having a parallel connected switch; and
switch states of each switch being configurable to selectively connect or disconnect one or more of said parallel and series capacitors.

In an embodiment, values of shunt capacitors are selected to provide coarse tuning steps and values of series capacitors selected to provide fine tuning steps, smaller than the coarse tuning steps, over a required reactance range; and values of shunt capacitors are selected to provide coarse tuning steps having uniform or non-uniform step sizes. Values of series capacitors are selected, e.g. to provide fine tuning steps having uniform step sizes over a required reactance range.

By way of example, values of switchable shunt capacitors are selected to provide coarse tuning steps in a range of about 20 Ω to 35 Ω, and values of switchable series capacitors are selected to provide uniform fine-tuning steps of about 5 Ω. The number of capacitors is selected to provide tuning over a maximum required inductance tuning range, and preferably the number of capacitors is selected to minimize or optimize the number of capacitors, e.g. to reduce unnecessary capacitative losses.

The circuit for load-adaptive auto-tuning circuit comprises a controller for receiving a trigger signal indicative of a reactance-shift (X-shift) and configuring switches (switch states) for switchably connecting one or more of said parallel connected capacitors and/or one of more of said series capacitors to provide a required reactance, e.g. based on a capacitance switching algorithm to implement coarse tuning and fine tuning of reactance. For example, the controller is configured to receiving a trigger signal indicative of a reactance-shift within an acceptable reactance range (window) and to configure switches for switchably connecting or disconnecting one or more of said parallel connected capacitors and/or one of more of said series capacitors to configure a switch state to provide one of: rough tuning steps, fine tuning steps, and a combination of rough tuning steps and fine tuning steps, to provide a required reactance, or at least to provide tuning close to a required reactance value. The controller may be further configured to operate switch means for triggering over-voltage protection or over-current protection on receiving a trigger signal indicative of a high impedance boundary value (exceeding an upper impedance window) or a low impedance boundary value (below a lower impedance window), said trigger signals being generated by the reactance-shift detection circuit. The reactance-shift detection circuit may be configured for operation with a PA with push-pull topology or single ended topology.

It is also contemplated that in alternative or additional embodiments, apparatus, systems and methods may comprise any feasible, i.e. practically implementable, and useful combinations of features defined the claims and described in the detailed description.

For example, a wireless power transfer (WPT) system comprising a resonator coil for generating a 3D magnetic field distribution for wireless charging within a 3D charging space (e.g. 3D TX coil), a power amplifier (PA), an impedance matching network, and a control system. The control system comprising at least one of a) a circuit to control current direction of a push-pull PA in response to a load condition, b) a reactance-shift (X-shift) detection circuit for triggering at least one of auto-tuning of reactance, over-voltage protection, and over-current protection, and c) a circuit for load-adaptive auto-tuning of reactance.

Thus, apparatus, systems and methods for load-adaptive 3D wireless charging are disclosed, comprising one or more of a 3D coil design, reactance-shift detection and auto-tuning.

### BRIEF DESCRIPTION OF THE DRAWINGS

FIG. 1 shows a simplified schematic diagram of an example resonant inductive WPT system;

FIG. 2 shows a schematic diagram to illustrate resonant inductive coupling of Tx and

Rx coils for charging of multiple devices;

FIG. 3 shows an equivalent circuit model for resonant inductive coupling of Tx and Rx coils for charging of multiple devices;

FIG. 4 shows an example of a Smith chart for input impedance Zin derived from the input reflection coefficient (S1,1), showing power contours and efficiency contours;

FIG. 5 (Prior Art) shows schematic representations of current wireless charging systems, comprising A. a flat planar charging pad or mat for wireless charging of a single mobile device such as a smart phone or tablet; B. an angled charging pad for a mobile device; and C. a flat planar charging pad for wireless charging of multiple devices, e.g. a smartphone, smartwatch and other small mobile device;

FIG. 6 shows a schematic diagram of a 3D resonator coil of an example embodiment, which is configured to provide a magnetic field distribution for charging of multiple devices over a 3D charging space providing hemi-spherical coverage;

FIG. 7 shows a schematic cross-sectional diagram of the 3D resonator coil of the embodiment shown in FIG. 6, with one mobile device placed in the 3D charging space;

FIG. 8 shows an example of a calibration grid for a magnetic field distribution configured for a hemi-spherical charging space/volume;

FIG. 9A and FIG. 9B show two photographs of a prototype 3D coil of an example embodiment comprising 5 turns, fabricated using PCB technology;

FIG. 10A and FIG. 10B show simplified schematic representations of single turn of an example 3D coil to illustrate current flow;

FIG. 10C and FIG. 10D shows simplified schematic representations of 3D coil topologies which are a variants of that shown in FIG. 6;

FIG. 11 shows (a) a model for calculating the z direction magnetic field (Bz) generated by a single loop Tx coil (cylindrical coordinates); (b) the calculated Bz distribution at various vertical separations of the Tx coil and an Rx coil; and (c) the calculated Bz distribution of a Tx coil comprising multiple circular turns;

FIG. 12 shows a model for calculating (a) the z direction magnetic field (Bz) generated by a horizontal part of a 3D Tx coil (cylindrical coordinates) and (b) the x direction magnetic field (Bx) generated by a vertical part of the 3D Tx coil; and (c) shows a schematic cross-sectional diagram through the 3D coil of the embodiment shown in FIG. 6, with three mobile devices positioned within the 3D charging space for wireless charging of each device;

FIG. 13 shows a high-level block diagram of a 3D charging system comprising a power transmitter unit (PTU) of an example embodiment and an example power receiving unit (PRU), e.g. a mobile device;

FIG. 14 shows a schematic block diagram of a power transmitting unit (PTU) of the example embodiment, comprising a PA having push-pull configuration, for controlling the direction of current flow through the 3D resonator coil;

FIG. 15 shows a high-level block diagram of the 3D charging system comprising a PTU of the example embodiment and a PRU comprising a calibration unit;

FIG. 16 shows schematic diagrams to illustrate (a) definition of 3 rotation angles and (b) projection area of a rotated z-coil;

FIG. 17 (Prior Art) shows a schematic block diagram of a PTU comprising a circuit for impedance detection using current, voltage and phase;

FIG. 18 (Prior Art) shows a schematic block diagram of a PTU comprising a circuit for impedance detection using peak drain voltage;

FIG. 19 (Prior Art) shows example data for conventional reactance detection using peak drain voltage (peak Vdrain) comprising: (a) a plot of example drain waveforms and results of peak detection for capacitance; (b) a plot of example drain waveforms and results of peak detection for inductance; (c) a plot of peak drain voltage Vdrain vs. reactance shift (jX); and (d) peak Vdrain vs. reactance shift (jX) simulation;

FIG. 20 shows a schematic block diagram of a PTU comprising a circuit for real-time impedance detection of an example embodiment comprising a single ended scheme for Class EF2 and Class E amplifiers;

FIG. 21 shows an example plot of V_{drain} at V_{PA}=48V, for Zin=20+30 j;

FIG. 22 shows example plots of V_{drain} at V_{PA}=48V, for a range of Zin=R+Xj, for 2≤R≤120 and 80≤X≤50;

FIG. 23 shows (a) a plot of phase angle θ vs. sin θ; and (b) a plot of angle θ vs. sin θ showing a linear approximation for 10≤θ≤70;

FIG. 24 shows a plot of example data for VSENSE*(VPHASE-VPHASE0)/ISENSE vs. Xj@ 1100 mA;

FIG. 25 shows examples of threshold values of vs. I_{TX} for A=−10, for the lower end of the impedance window;

FIG. 26 shows examples of threshold values vs. I_{TX} for A=0, for the upper end of the impedance window;

FIG. 27 shows a functional block diagram of a circuit of an example embodiment for real-time impedance window detection, for enabling auto-tuning;

FIG. 28 shows Smith charts for test data using the impedance detection circuit of FIG. 27 for a) a lower end of the impedance window −10 Ohm; and (b) an upper end of the impedance window 0 Ohm;

FIG. 29 is a flow chart to illustrate a method of detection of an impedance window for auto-tuning according to an example embodiment;

FIG. 30 shows an example of a phase detection circuit design;

FIG. 31 shows an example of a planar current coupler circuit design;

FIG. 32 shows a schematic diagram of part of a circuit comprising a planar current coupler;

FIG. 33 shows an example of a voltage sensor circuit design;

FIG. 34 shows a schematic block diagram of a PTU comprising a circuit for impedance detection of an example embodiment comprising a push-pull scheme for Class EF2 and Class E amplifiers with real-time current, voltage and phase sensing for X detection;

FIG. 35 shows a schematic diagram of a mobile communications device, such as a smartphone or tablet with the back cover removed to show its Rx coil for wireless charging;

FIG. 36 shows a schematic diagram of mobile device, such as a tablet, positioned on a planar charging pad to illustrate eddy currents generated by the metal chassis and components adjacent to Rx coil;

FIG. 37 shows a 3D transmitter coil of an example embodiment;

FIG. 38 shows a schematic diagram to illustrate a single mobile device positioned in the 3D charging space of the 3D transmitter coil of FIG. 37;

FIG. 39 shows a schematic diagram to illustrate multiple mobile devices positioned in the 3D charging space of the 3D transmitter coil of FIG. 37;

FIG. 40 shows a series schematic diagrams (a) to (e) of switch states of an adaptive tuning circuit and corresponding Smith charts to show input impedances; and diagram (f) shows a reactance shift range of adaptive tuning with efficiency and power contours; wherein adaptive tuning with shunt capacitances is controlled by mechanical relays or switches;

FIG. 41 shows an adaptive tuning circuit comprising a series/parallel (fine/rough) tuning capacitor arrangement for a single-ended PA configuration;

FIG. 42 shows an adaptive tuning circuit comprising a series/parallel (fine/rough) tuning capacitor arrangement for a push-pull PA configuration;

FIG. 43 shows a series of schematic diagrams (a), (b) and (c) of an adaptive tuning circuit for different switch states of switches S1, S2, S3 and S4 for rough and fine tuning of input impedance, with corresponding Smith charts to shown input impedances;

FIG. 44 shows Smith charts (a), (b) and (c) to illustrate the reactance shift range for adaptive tuning of reactance with fine and rough tuning, wherein rough-tuning covers a larger impedance area with bigger step size and fine-tuning covers a smaller impedance area with smaller uniform step sizes;

FIG. 45 shows a table of sample data for rough and fine tuning;

FIG. 46 shows a plot of tuning range and step size for A. fine tuning (5 Ωsteps); B. a combination of 4 step rough tuning steps and 11 fine tuning steps; C. rough tuning (15 Ωsteps); and D. uniform tuning steps;

FIG. 47 shows a flow chart for a method of auto-tuning comprising determining and controlling rough and fine tuning according to an example embodiment;

FIG. 48 shows circuit schematic of an example Class E constant current PA topology; and

FIG. 49 shows circuit schematic of an example Class EF2 constant current PA topology.

The foregoing and other features, aspects and advantages of the present invention will become more apparent from the following detailed description, taken in conjunction with the accompanying drawings, of embodiments of the invention, which description is by way of example only.

### DETAILED DESCRIPTION

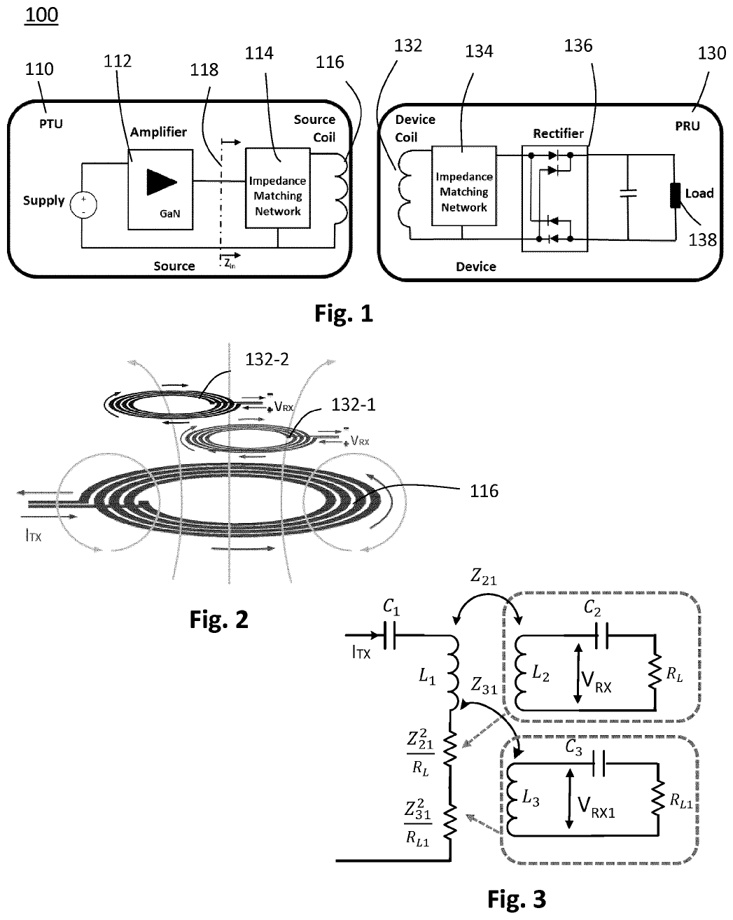

An example of a resonant inductive wireless power transfer (WPT) system 100 is shown schematically in FIG. 1. In this WPT system 100, the source or transmitter (Tx) may be referred to as a power transmitter unit (PTU) 110, and comprises an RF source in the form of a power amplifier (PA) 112, an impedance matching network 114, and a Tx resonator coil (source coil) 116. The PA 112 drives the system and is modeled as an ideal constant current source. The receiver and its load, e.g. a mobile device to be powered or charged, may be referred to as a Power Receiving Unit 130. The PRU 130 comprises a Rx resonator coil 132, and impedance matching network 134, and a rectifier 136, e.g. a diode bridge. The device being charged or powered is represented by the load 138. The diode bridge 136 is used to rectify the input RF signal into a DC signal, e.g. for powering the device or charging a battery. The PA 112 sees an input impedance Zᵢₙ in reference plane A (118). The magnetic field providing resonant inductive coupling of a Tx coil 116 and Rx coils, e.g. 132-1 and 132-2, of multiple devices is represented schematically in FIG. 2. An equivalent circuit model for an example resonant WPT system for charging multiple devices, e.g. first and second devices 130-1 and 130-2 is shown in FIG. 3.

Embodiments of devices, systems and methods for load-adaptive 3D wireless charging of single or multiple devices will now be described by way of example, comprising, e.g.: coil design and operation for generating a magnetic field distribution over a hemi-spherical charging space for charging multiple devices; real-time reactance shift detection (X-shift detection); and auto-tuning of input impedance, to address one or more issues, such as maintaining a safe operating temperature, e.g. to operate the charging station in a high efficiency range to limit unwanted thermal dissipation and improve system reliability and/or limiting over-current or over-voltage conditions and thermal overload of the PA, which may arise from a load which is too inductive or too capacitative.

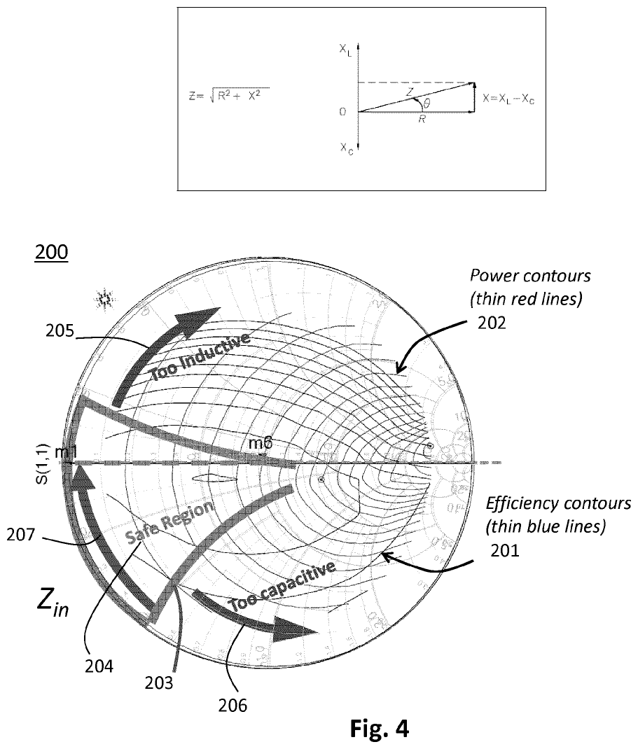

FIG. 4 shows an example of a Smith chart for representing a reactance shift range for load-adaptive tuning, with efficiency contours 201 (thin blue lines in the color version of FIG. 4) and power contours 202 (thin red lines in the color version of FIG. 4). As shown in this example Smith chart, for optimum performance in operation of a WPT system, there is typically a region wherein the input impedance Zᵢₙ, efficiency and power, are optimized, e.g. within boundary lines 203 (thick green lines in the color version of FIG. 4) which outline a safe region 204. Outside this region 204, the input impedance may be too capacitative 206 or too inductive 205 (as indicated in the regions with red arrows) resulting in poor efficiency or poor reliability. As indicated by the blue arrow 207, it is desirable to tune the input impedance Zin to a value within a range for safe operation, e.g. within safe region 204.

The Tx and Rx coils are an important subsystem of a WPT system. For example, based on AirFuel Resonant specifications, these coils (also called resonators, or resonator coils) are required to exhibit certain performance characteristics. For example, current AirFuel Resonant specifications are limited to WPT for a maximum gap of 50 mm and a maximum power of 70 W.

Flat planar resonator coils may be fabricated using conventional PCB technology, e.g. the turns of the coil are formed by conductive metal traces, e.g. copper traces, supported on or in a dielectric substrate. For a planar coil, the dominant magnetic field component is along the z direction, i.e. H_{z}, perpendicular to the plane of the coil.

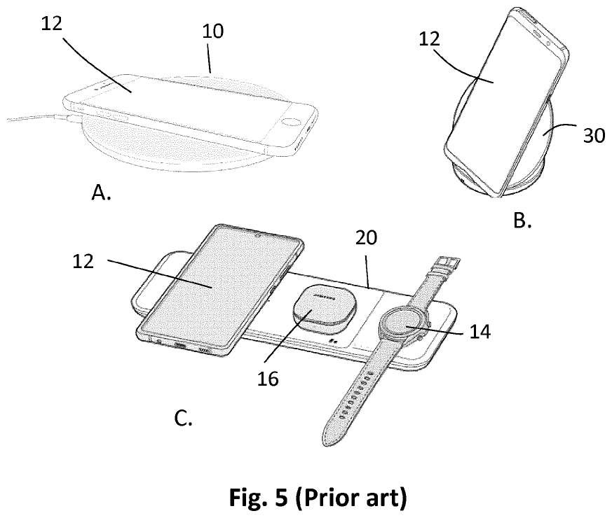

Some examples of wireless charging systems comprising a planar charging pad for mobile and wearable devices are shown in FIG. 5. For example, in FIG. 5, view A. shows a schematic representation of a flat planar charging pad or mat 10 for wireless charging of a single mobile device 12, such as a smart phone or tablet; view B. shows a planar charging pad 30 for a smartphone 12 in the form of an angled stand; and view C. shows a planar charging pad 20 for wireless charging of multiple devices, e.g. a smartphone 12, smartwatch 14 and other small mobile devices 16. Since each device is placed on the charging pad, although these types of wireless charging systems are convenient for periodic charging, e.g. overnight charging, they do not allow a user to use the device easily while it is charging.

As mentioned above, charging stations are now being developed for 3D wireless charging of one or multiple mobile devices, e.g. to offer more spatial freedom and a larger gap between the charging station and a mobile device. For example, there is a need for 3D charging systems that can generate a 3D magnetic field, at a charging station, which allow for a user to continue to use using a mobile device, such as a smartphone, while it is charging, and which do not require the user to let go of the device, e.g. place it on a charging pad, while it is charging. For example, in a coffee shop environment, multiple users may wish to continue browsing or texting, while their devices are charging. In this scenario, each user may therefore wish to hold their device in a comfortable orientation and move the device in the charging space. Thus, there is a need for 3D wireless charging systems that generate 3D magnetic fields and systems that can dynamically adapt to positioning of one or more devices at a charging station, e.g. to provide dynamic load dependent impedance detection and impedance matching to maintain efficient operation of the power amplifier of the transmitter.

For example, a 3D charging system of an example embodiment is disclosed herein that comprises the following elements/features:
1. A 3D coil design comprising a single coil which provides magnetic field distribution coverage for 3D charging space (e.g. a hemi-spherical space/volume);
2. A push-pull class EF2 PA with EMI filter, and transmitter circuitry that provides a constant current to the 3D coil, with current direction control capability;
3. A reactance-shift detection circuit with voltage sensor, current sensor and phase detector for fast real-time, reactance-shift (X-shift) detection.

Also disclosed is a system calibration unit for calibrating the system for multiple device positions and orientations, to establish a reference 3D field for actual charging of mobile devices. For example, the 3D charging system may comprise a microcontroller, on the printed circuit board (PCB) of the transmitter, that saves calibration data, and also processes and communicates the orientation and positioning information of each mobile.

### 3D Transmitter Coil Design

One aspect of the inventions disclosed herein provides a 3D Tx coil design for a 3D wireless charging system for multiple mobile devices such as phones, tablets and wearable devices. For example, in an example embodiment, the 3D Tx coil is designed for a MHz frequency, e.g. 6.78 MHz, wireless charging system with a targeted charging range (distance between Tx and Rx coils) of about 200 mm to 300 mm, for creating a magnetic field distribution with 3D coverage in a charging space or volume of about 300 mm by 300 mm by 300 m, e.g. a typical reachable space for office and public facilities.

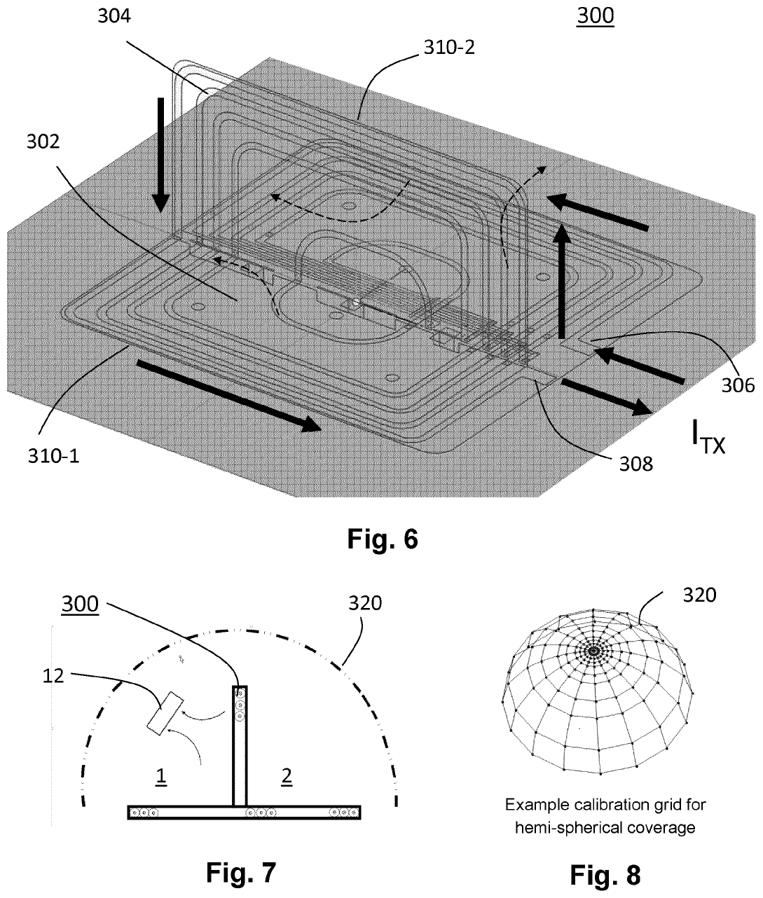

A schematic diagram of a 3D Tx resonator coil 300 of an example embodiment which provides a 3D magnetic field for charging of multiple devices is shown in FIG. 6. FIG. 7 shows a schematic cross-sectional diagram of the 3D resonator coil 300 of the embodiment shown in FIG. 6, with one mobile device 12 placed in the 3D charging space. The coil comprises a dielectric support (substrate) 302 and conductive traces 304 patterned to define a coil topology comprising a plurality of turns, and first and second feed ports 306, 308. For example, the coil may be fabricated using PCB technology, comprising a dielectric substrate, such as a FR4 type material, where the turns of the coil topology are defined by conductive traces defined by one or more metal layers in or on the dielectric substrate. Each turn comprises a first part 310-1 wherein said conductive traces are defined in a first plane, e.g. xy plane, and a second part 310-2 wherein said conductive traces are defined in a second plane, which is orthogonal to the first plane, e.g. xz plane, as illustrated schematically in FIG. 6. In this example, the coil topology is configured to generate a three-dimensional (3D) magnetic field distribution for wireless charging within a 3D charging space, e.g. a three-dimensional magnetic field distribution for wireless charging within a hemi-spherical charging space 320 as illustrated schematically in FIG. 7 and FIG. 8.

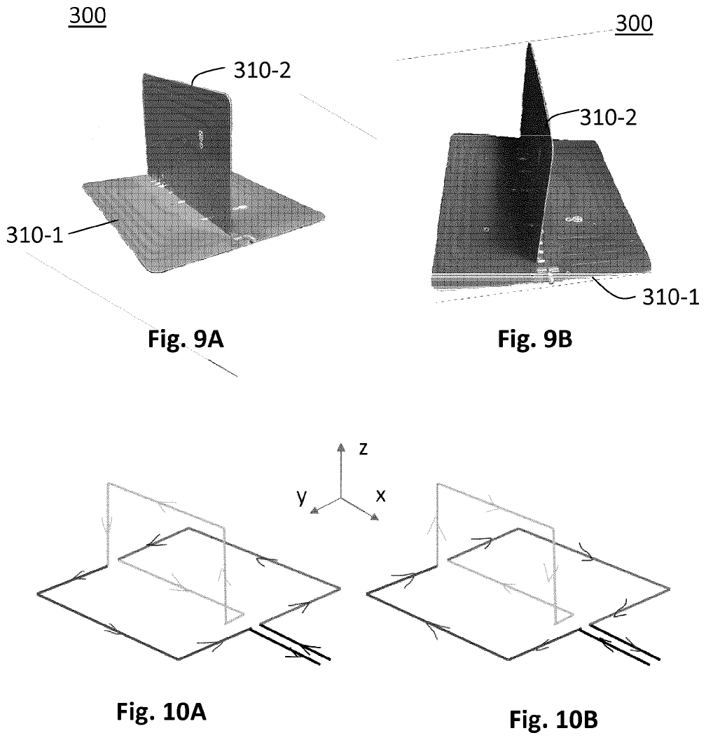

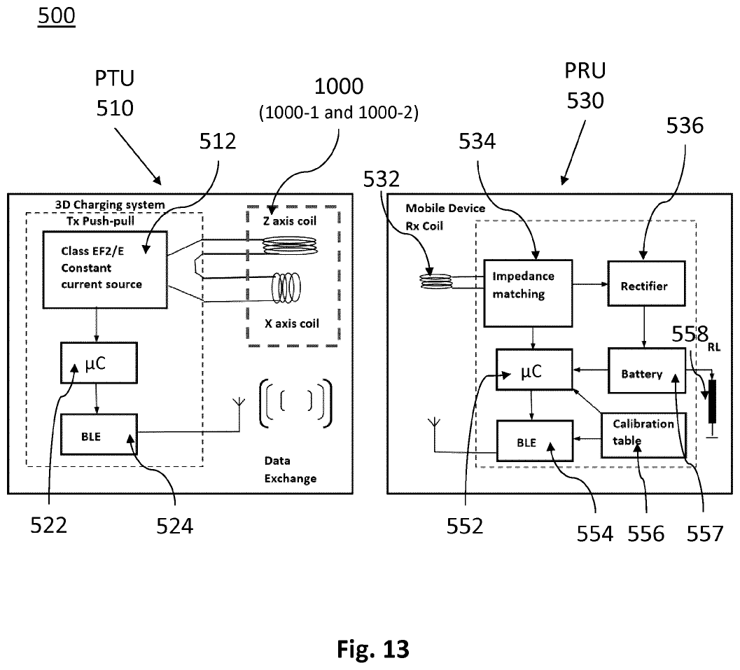

For example, the coil may be fabricated using PCB technology, in which conductive metal traces are supported by (in or on) a dielectric substrate. FIG. 9A and FIG. 9B show photographs of a prototype 3D coil fabricated using PCB technology, in which the xy part of the coil is fabricated on a first part 310-1 of the substrate in the first plane and the xz part of the coil is fabricated on a second part 310-2 of the substrate mounted in the second plane. The two parts are interconnected at 90 degrees, i.e. the first and second parts of the substrates are mechanically bonded and the conductive traces on each of the first and second parts of the substrates are electrically interconnected to form a single (contiguous) coil, with the first and second feed ports for connection to a power source. Thus, e.g. the first plane comprises an xy plane, and the second plane comprises a xz plane, and the charging space comprises a first half and a second half on opposite sides (i.e. −y and +y sides) of the xz plane (e.g. see FIG. 7 and FIG. 12(c)).

Thus, if the 3D coil is placed on a surface such as a tabletop or desktop, the hemi-spherical (half-global) charging space is divided into two halves, i.e. first and second quadrants 1 and 2 of the charging space, by the vertical xz part of the 3D coil. One device or multiple devices to be charged may be placed in one or both quadrants 1 and 2 of the charging space (see FIG. 12(c)).

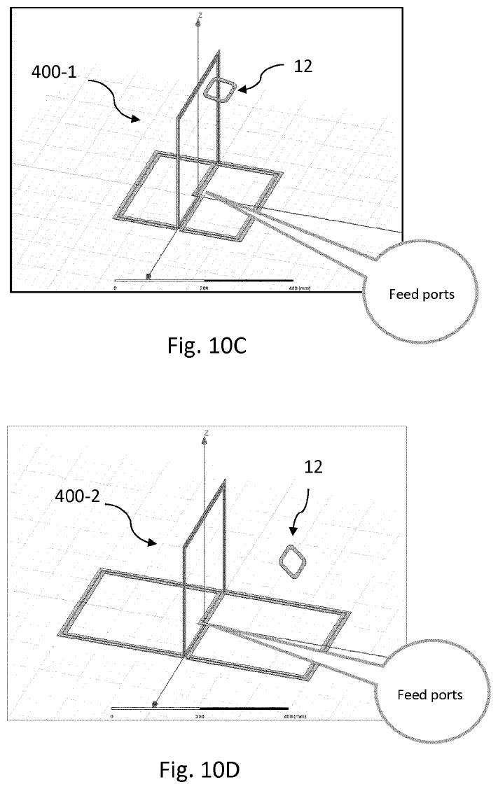

The 3D coil of this embodiment is a single coil having a plurality of turns, each turn having first part in a first plane comprising a plurality of xy turns that generate a z component Bz of a 3D magnetic field and a second part which is orthogonal, e.g. comprising a plurality of zx turns that generate a component of the 3D magnetic field which is orthogonal to the z component, e.g. a By field. The interconnections of the xy and zx turns are made to form a single coil for generating a 3D magnetic field, when it is driven by a single PA, having either a single-ended or push-pull topology. The solid black arrows in FIGS. 6 illustrate schematically a direction of current flow. The dotted arrows represent schematically some magnetic field lines. FIGS. 10A and 10B show schematic representations of current flow in each direction for one turn of a coil, such as that shown in FIGS. 9A and 9B.

The coil parameters, e.g. coil dimensions, and trace widths and trace spacings of each turn of the coil, are configured to provide a required magnetic field distribution to meet system performance requirements. For example, the coil dimensions and trace widths and trace spacings may be designed to optimize a uniformity of the magnetic field distribution within the charging space (e.g. see the above referenced US62/947,144). The example coil topology shown in FIG. 6 comprises 5 turns, each part of the turns being substantially rectangular with rounded corners. The coil may alternatively be seen as having 3 lobes, turns of each lobe comprising a half-loop which is rectangular with rounded corners, e.g. 2 lobes extend in the xy directions and 1 lobe is orthogonal in the xz (or yz) direction, and the lobes are interconnected in series to form a single coil, which can be driven by a single PA. This topology is shown by way of example only. For example, to provide a hemi-spherical 3D charging space, the vertical height (z height) of the xz part of the coil is about half the width of the xy part of the coil (e.g. z height=y and −y dimensions). However, these dimensions may be varied, as shown, for example, in the schematic diagrams in FIGS. 10C and 10D which illustrate some coils 400-1 and 400-2 of other example embodiments, for charging a mobile device 12. The coils 400-1 and 400-2 have different aspect ratios, and the feed ports are located at different positions from the feed ports 306 and 308 shown for a 3D coil of the example embodiment illustrated schematically in FIG. 6.

The shape of the coil, the number of turns, and dimensions of each turn are provided by way of example only. The geometry of each part loop could be varied, e.g. it could be more circular, or semi-circular, or rectangular or triangular, to provide a required magnetic field distribution, over a hemi-spherical charging space, or other specified 3D charging space.

### System Architecture and Flow

As described further below, in an example embodiment of a 3D wireless charging system, the 3D coil is driven by a single PA current source. This is possible because the xy and xz parts of the n turns of the coil are connected in series and configured to form a single coil, which is connected to a single PA constant current source, to generate a hemi-spherical (half-global) magnetic field distribution over a 3D charging space.

For comparison, in known prior art 3D WPT systems that use multiple orthogonal Tx coils, e.g. two or three individual coils, to create a magnetic field distribution, there is coupling or interference between the multiple coils if they operate at the same frequency, and multiple PAs are required, i.e. one per coil, and each coil may operate at a different frequency to reduce interference and coupling.

In a system for 3D charging of multiple devices using a 3D coil topology, to provide dynamic load-adaptive 3D wireless charging a number of features are now described.

In embodiments in which the PA comprises a push-pull configuration, the current feeding (i.e. current direction) of the coil is configurable to maintain an appropriate magnetic field distribution, e.g. dependent on the number and placement of mobile devices, and built-in impedance detection is provided to identify positions of multiple mobile devices in the charging space (volume) and further adjust the current direction to balance the coil loading of the two halves the PA. Gyroscope data received from the mobile devices may be helpful in determining positioning of the mobile devices, e.g. to increase coupling efficiency, or, assist in positioning of the mobile devices. For example, in a wireless charging system based on an AirFuel compliant 6.78 Mhz magnetic field, multiple devices may be charged simultaneously, and short range out-of-band communication channel, e.g. using Bluetooth, provides a control channel for exchange of parameters between the charging station and the mobile device to be charged.

The objective of the 3D coil design is to construct a magnetic field distribution covering a half-global area (i.e. hemi-spherical volume) so that the charging system can provide positional freedom for charging of mobile devices in a specified charging space, e.g. a 300 mm by 300 mm by 300 mm space. Mobile devices do not have to be placed on a pad, so that devices could be charging when still in use, e.g. when a user is holding the device in a typical use position and orientation for e.g. texting, web surfing, or replying to email.

For example, photographs of a 3D coil of a prototype embodiment is shown in FIGS. 9A and 9B. The coil 300 is made using PCB technology, i.e. the coil is defined by conductive metal traces formed in/on a dielectric substrate. The coil design combines two coil parts having physically orthogonal positions: horizontal 310-1 and vertical 310-2, into a single coil, as is shown schematically in FIG. 6. The two parts are mechanically bonded, and the conductive traces are electrically connected. The current I_{Tx}, is fed through the turns of the coil to generate the 3D magnetic field. The coil may be driven by single PA with push-pull configuration so that the current direction is controllable. FIGS. 10A and 10B show schematic diagrams to illustrate current flow, in each direction, through one turn of a coil having a topology such as illustrated in FIGS. 9A and 9B.

### Coil Design Theory

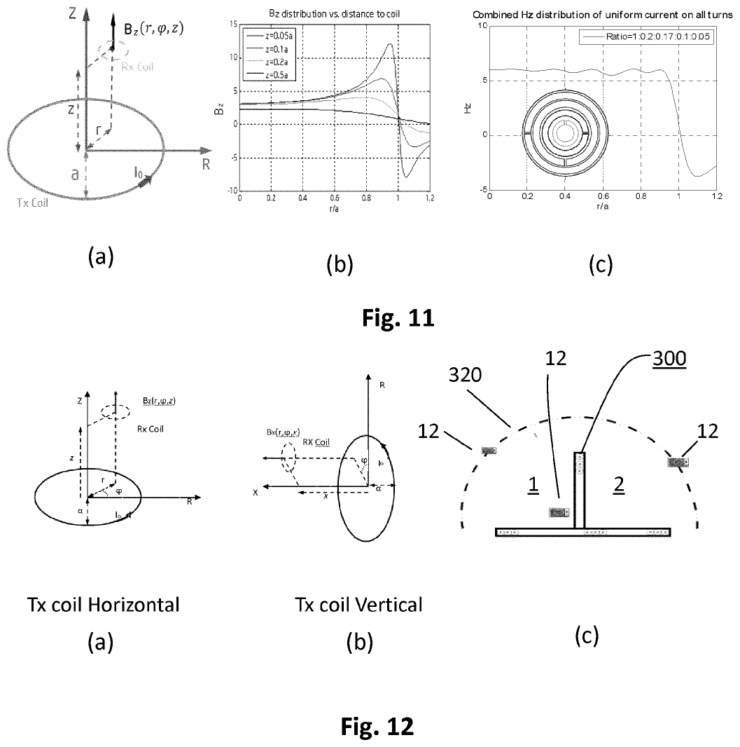

The Z direction magnetic field (Bz) of a single turn circular coil centered at origin, as illustrated schematically in FIG. 11 (a) and FIG. 11 (b), can be described as follows:

$${B}_{z} ( r , φ , z ) = \frac{{μ}_{0} {I}_{0}}{2 π \sqrt{{( r + a )}^{2} + {z}^{2}}} \cdot [ K ( {k}_{c} ) - \frac{{r}^{2} - {a}^{2} + {z}^{2}}{{( r - a )}^{2} + {z}^{2}} E ( {k}_{c} ) ] \qquad ( 1 )$$

where,

$${k}_{c}^{2} = \frac{4 a r}{{( r + a )}^{2} + {z}^{2}} .$$

K(k) and E(k) are, respectively, the complete elliptic integral functions of the first and the second kind.

As shown in FIG. 11 (c), optimization of spacing and width of a turns of a multiple turn coil can provide a more even distribution at an elevation of z. Per the superposition theory of multiple orthogonal coils, the magnetic field is individual coil contribution, the total magnetic field at mobile devices charging position is derived in equation (2):

$$B = {B}_{z} ( rz , φ z , z ) + {B}_{x} ( rx , φ x , z ) = \frac{{μ}_{0} {I}_{0}}{2 π \sqrt{{( r z + a z )}^{2} + {z}^{2}}} \cdot [ K ( {k}_{c z} ) - \frac{r {z}^{2} - a {z}^{2} + {z}^{2}}{{( r z - a z )}^{2} + {z}^{2}} E ( {k}_{c z} ) ] + \frac{{μ}_{0} {I}_{0}}{2 π \sqrt{{( r x + a x )}^{2} + {x}^{2}}} \cdot [ K ( {k}_{c x} ) - \frac{r {x}^{2} - a {x}^{2} + {x}^{2}}{{( r x - a x )}^{2} + {x}^{2}} E ( {k}_{c x} ) ] \qquad ( 2 )$$

$$where , {k}_{cz}^{2} = \frac{4 a z . r z}{{( r z + a z )}^{2} + {z}^{2}} ; {k}_{cx}^{2} = \frac{4 ax . rx}{{( r x + a x )}^{2} + z {x}^{2}} .$$

FIG. 12 shows a model for calculating (a) the z direction magnetic field (Bz) generated by a horizontal part of a 3D Tx coil (cylindrical coordinates) and (b) the x direction magnetic field (Bx) generated by a vertical part of the 3D Tx coil; and (c) shows a schematic cross-sectional diagram through the 3D coil 300 of the embodiment shown in FIG. 7, with three mobile devices 12 positioned within the 3D charging space for charging. Mobile devices in the 3D charging space generated by the Tx coil are depicted by Rx coils in FIG. 12 (c). For example, two coil parts are designed to provide the required Bz and Bx fields and these are merged into one coil (e.g. connected in series as shown in FIG. 6 with optimization of the number of turns, spacing and trace widths of each turn to meet performance requirements, e.g. to optimize magnetic field distribution uniformity in the 3D charging space 320.

### Optimization of loading condition of 3D coil

A high-level block diagram of a 3D charging system 500 comprising a PTU 510 with a 3D coil 1000 comprising orthogonal coil parts, comprising a z-axis coil element 1000-1 and an x-axis coil element 1000-2 integrated in series as a single coil, driven by a single PA 512 is shown in FIG. 13. The PTU 510 includes a micro-controller 522 and a module for an out of band communication channel, such as Bluetooth module 524.

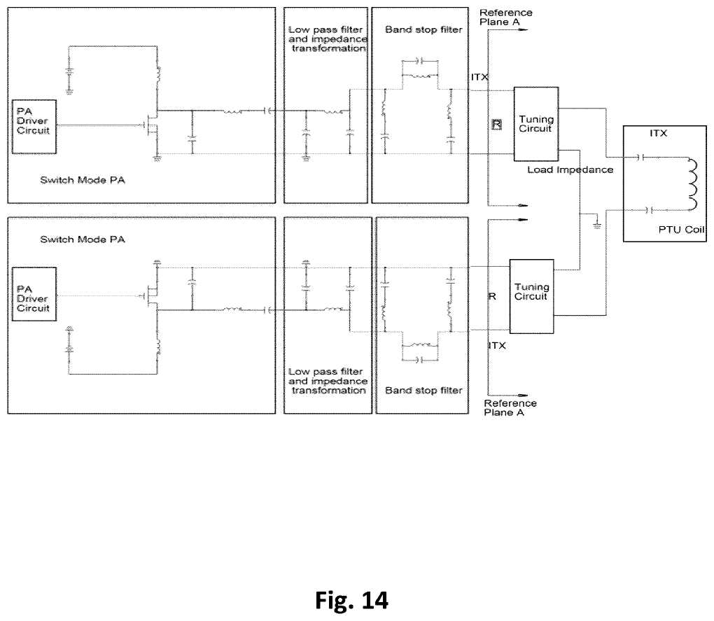

A simplified schematic block diagram of a PTU 510 with a push-pull configuration, wherein the direction of current flow is configurable, is shown in FIG. 14. In an example scenario, multiple devices are placed in the 3D charging space, and the magnetic field distribution is not even in the two halves of the hemi-spherical space shown in FIG. 12 (c). Also, the loadings of the two orthogonal parts of the coil are not same if there is an odd number of devices in the charging space. For example, if there are 3 mobile devices in the charging space, the number distribution of devices in the two halves of the space could be 0:3 or 3:0 or 2:1 or 1:2; and for an even number of devices, it could be 1:1 or 0:2 or 2:0.

Changing the direction of the charging current direction on the coils can be used to balance the loading of the two halves of magnetic field; e.g. the current flow direction is controllable based on a loading condition in the 3D charging space. Also, the interval time of the current flow on each part of the coil can be changed. The identification of the loading condition may be based on a calibration table which is created and saved in the MCU with gauge devices at all elevations, e.g. using a calibration grid such as shown in FIG. 8. The calibration process is described in more detail below.

### System Architecture & Flow

FIG. 13 shows a high-level block diagram of a 3D charging system 500 of an embodiment comprising a PTU 510 including a Class EF2 or Class E constant current source 512 and a Tx coil 1000 configured for generating a 3D magnetic field distribution, and a mobile device to be charged. The PRU 530 of the mobile device receiving system may be integrated into the mobile device, as illustrated schematically, or the PRU 530 may be a separate individual receiver. The PRU 530 may comprise a Rx resonator coil 532, and impedance matching network 534, a rectifier 536, e.g. a diode bridge, a micro-controller 552, a Bluetooth module 554, a calibration table 556, and a battery 557. The device being charged or powered is represented by a load 558.

An example embodiment of a Class EF2 3D charging system comprises the following components:
A MHz frequency (e.g. AirFuel compliant frequency) constant current source which provides AC current to the Tx coil.
A 3D transmission coil: the coil generates the magnetic field used to establish magnetic field distribution (e.g. for both mobile devices charging, and for use of a calibration device to generate a calibration table);
a microcontroller (μC), which
   a) controls the transmission of PA current and current direction supplied to the Tx coil, based on loading conditions;
   b) performs calculation of the orientation of the receiver coil;
   c) controls the PA current based on the calibration table.
a control channel, e.g. an out of band radio system (e.g. Bluetooth low energy) to receive the field measurement results reported in system calibration, and report the mobile device status during a charging operation.

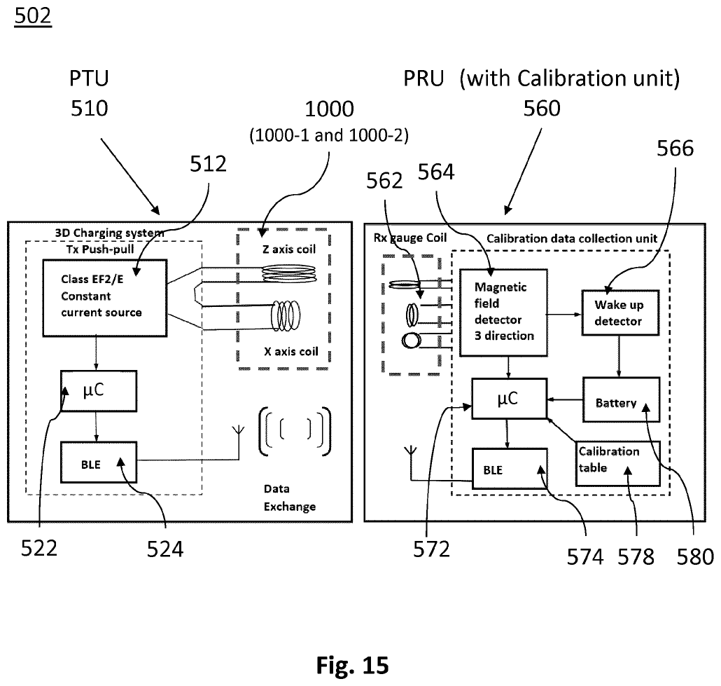

For calibration, a 3D calibration system comprising a calibration unit is provided. A 3D orientation calibration coil is used to provide the magnetic field for 3D charging space to calculate its orientation based on the 3-component magnetic field measured. FIG. 15 shows a high-level block diagram of the 3D charging system comprising a PTU 510 of the example embodiment and a PRU 560 comprising a calibration unit. The PRU 560 may comprise a Rx resonator coil 562, a magnetic field detector (3 direction) 564, a wake up detector 566, a micro-controller 572, a Bluetooth module 574, a calibration table 578, and a battery 580.

Receiver coil design for optimum efficiency of 3D charging system

For two circular coils that have the same normal direction, the induced voltage on the receiver coil can be written as:

V=2πfQ·Bₜₒₜₐₗ×A₀·N=2πfS·(B_{z}×A_{z}BₓAₓ) (3)

where the Q represents the quality factor of the receiver coil, Bₜₒₜₐₗ is the total magnetic field generated by the transmitter coil and A₀ is the equivalent area of the receiver. B_{z} and Bₓ are the magnetic fields generated by z direction coil and x direction coil. A_{z} and Aₓ are the areas of the receiver coil on the z and x axis planes respectively, N is the number of turns of receiver coil. When the orientation of the mobile devices is not fixed during charging in the 3D system, a conventional planar receiver coil does not provide maximum efficiency. To improve or optimize charging efficiency, the receiver coil of the mobile device is preferably a 3D coil instead of a planar one. Ideally, turns of the 3D receiver coils should have similar side length at each edge, e.g. a more symmetrical shape, such as square or circular in shape. The magnetic field sensitivity S=Q·N (V/Tesla). An example receiver coil design topology may comprise conductive traces that are provided on a non-planar substrate surface, e.g. several turns of conductive wires are wound on a curved form, e.g. part of a spherical surface of an appropriate radius, to provide a non-planar 3D coil having a height of e.g. ˜10 mm, designed to improve 3D coupling for better efficiency.

### Algorithm for Bₜₒₜₐₗ Calculation and Gauge Coil Calibration for Rotation Angles Of Mobile Devices

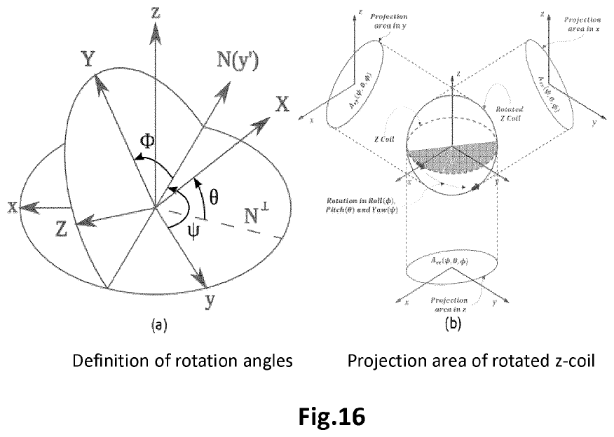

In order to solve for the 3 magnetic field components (Bx, By, Bz) from measured voltages from 3 orthogonal gauge receiver coils, accurate information on orientation of the receiver gauge coil is required for calibration. Such information can be gathered by a gyro sensor on the receiver or through magnetic field calibration, as will be discussed later. The orientation of the gauge receiver coil can be defined using rotation along 3 axes (z-y′ and x″), i.e. Roll (Φ), pitch (θ) and yaw (ψ), as shown in FIG. 16 (a).

Based on this definition, for any coil after the rotation, the projection area of the coil onto the 3 major planes (x-y, y-z, and y-x) can be calculated and expressed as matrix A:

$$A = [ \begin{matrix}{A}_{xx} & {A}_{y x} & {A}_{z x} \\ {A}_{x y} & {A}_{y y} & {A}_{z y} \\ {A}_{x z} & {A}_{y z} & {A}_{zz}\end{matrix} ] = π {b}^{2} [ \begin{matrix}cos ψcosθ & cos ψsinθsinϕ - cos ϕsinψ & sin ψsinϕ + cos ψcosϕsinθ \\ cos θsinψ & cos ψcosϕ + sin ψsinθsinϕ & cos ϕsinψsinθ - cos ψsinϕ \\ - sin θ & cos θsinϕ & cos θcosϕ\end{matrix} ] \qquad ( 4 )$$

where b is the radius of the circular guage receiver coil. As shown in FIG. 16 (b), A_{zy} denotes the projection area of z direction coil (on x-y plane, z as normal direction) onto the x-z plane. With these definitions, the relationship between measured voltage and the orientation of the coil can be derived as:

$$V = [ {V}_{x} {V}_{y} {V}_{z} ] = 2 π fS \cdot B \times A = 2 π fS \cdot [ {B}_{x} {B}_{y} {B}_{z} ] \times [ \begin{matrix}{A}_{xx} & {A}_{y x} & {A}_{z x} \\ {A}_{x y} & {A}_{y y} & {A}_{z y} \\ {A}_{x z} & {A}_{y z} & {A}_{zz}\end{matrix} ] \qquad ( 5 )$$

where Vx, Vy, Vz, represents the measured voltages from the 3 orthogonal coils, and Bx, By, Bz are 3 components of an unknown magnetic field generated by the 3D charging Tx coil, which can be solved by:

$$[ {B}_{x} {B}_{y} {B}_{z} ] = \frac{1}{2 {b}^{2} {π}^{2} fS} \cdot [ {V}_{x} {V}_{y} {V}_{z} ] \times {[ \begin{matrix}cos ψcosθ & cos ψsinθsinϕ - cos ϕsinψ & sin ψsinϕ + cos ψcosϕsinθ \\ cos θsinψ & cos ψcosϕ + sin ψsinθsinϕ & cos ϕsinψsinθ - cos ψsinϕ \\ - sin θ & cos θsinϕ & cos θcosϕ\end{matrix} ]}^{- 1} \qquad ( 6 )$$

For example, for calibration positions of a calibration grid such as shown in FIG. 8, a calibration table is calculated for Bz from 3 coil voltage measurements, and the impedance of Tx output. All this information is indexed into a calibration table.

In an actual test system, to simplify, the gauge coil includes two axis coils only, so the matrix (6) included two terms only.

### Reactance Shift Detection (X Detection)

In operation of a WPT system as illustrated schematically in FIGS. 1 to 3, to achieve optimized system efficiency, it is important to keep the effective load seen by the PA, i.e. input impedance Zᵢₙ at reference plane A, within a certain range in which the PA operates at highest efficiency, e.g. as shown in the example Smith chart 200 in FIG. 4. Zᵢₙ is closely related to the coupling system, rectifier and load condition. Different devices and different tuning and operational conditions define different Zᵢₙ at the reference plane A of the output of the PA. FIG. 4 is a Smith chart which illustrates an example of an ideal Zᵢₙ region, denoted by green contours outlining a safe region 204, for a class EF2 PA design. The load is considered either too inductive or too capacitive outside of the high efficiency operation region, which respectively cause over-current and over-voltage conditions in the PA. In extreme cases, presenting the PA to high inductive impedance conditions could damage the device due to thermal effects (overheating) due to high dissipation power. A WPT system which supports larger charging distances, larger charging areas or spaces, and charging of multiple devices can cause large variations of Zin, over a wide impedance range. These are particular challenges for high power magnetic resonance 3D wireless charging systems.

For low power applications in the WPT industry, most systems operate without tuning systems or a simple tuning system. But for the higher power applications, or a more complicated WPT system, such as 3D charging system for multiple devices, an auto tuning system becomes necessary for improved system reliability. Therefore, a solution for detecting an over-dissipation condition is desirable, to supplement existing reactance shift detection and auto-tuning solutions, to avoid low efficiency operation, which could cause over temperature in the 3D charging system.

Existing solutions for impedance detection are based on calculation, e.g. using current, voltage and phase information, or using peak drain voltage detection.

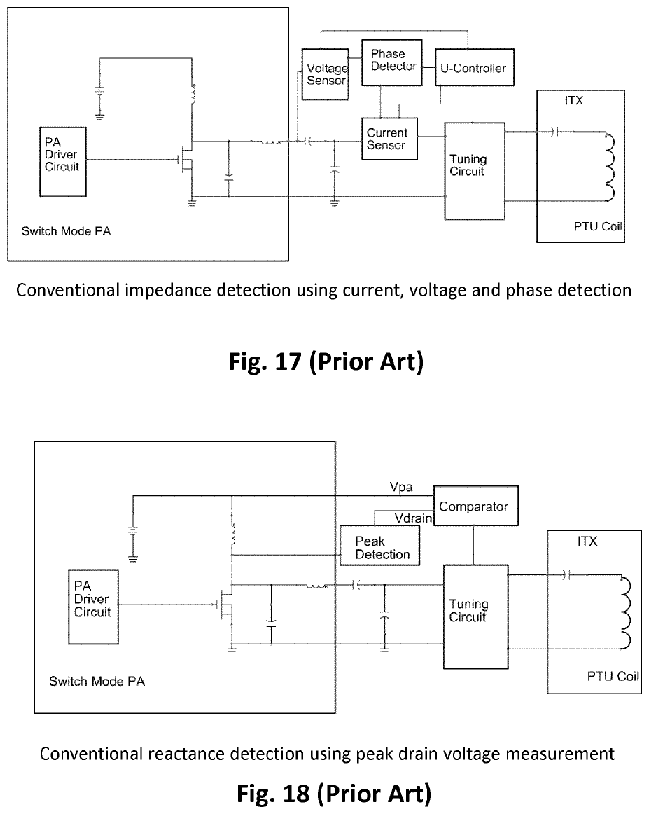

For example, conventionally, a voltage sensor, current sensor and phase detector can be used to determine the load condition. As shown in FIG. 17 (Prior Art), a current sensor, voltage sensor and phase detector are added in between the switch mode PA and the tuning circuit of the PTU coil. The voltage magnitude (V), current magnitude (I) and phase between current and voltage (ϕ) are input to the ADC of a micro-controller in order to determine the triggering condition, based on a calibration table. The micro-controller digitizes and computes the load impedance where:

|Z|=|V|/|I| R=|Z|·cos φ jX=j|Z|·sin φ (1)

Based on the calculated jX value, the micro-controller decides whether to address the auto-tuning circuit to switch-in or switch-out one or more tuning capacitors, or in extreme cases, to trigger protection mechanisms.

However, this scheme relies on a high-speed microcontroller (e.g. a GHz processor) to calculate the reactance shift (jX) in real-time. To reduce costs of a typical transmitter system for WPT applications, the microcontroller is a low-cost processor with a low clock speed. This means that the cycle time of the control loop is inherently slow, which may not be robust enough to handle fast varying reactance shifts on the PTU coil in real-time, e.g. when the multiple devices are placed/removed/rotated in the charging 3D area.

In another example conventional method for reactance shift detection, the peak drain voltage Vdrain is used to implicitly determine a reactance shift (FIG. 18 (Prior Art)). The PA is configured so that the ratio between peak Vdrain and the DC supply voltage of the PA, VPA, reflects the reactance shift of the load (e.g. see US2017/0187355A1). This method can be implemented by simple logic hardware. As shown in FIG. 18, the circuit is a simple and effective solution for reactance detection of a Class E PA for auto-tuning purpose, but it does not work very well for a Class EF2 PA. Another example method for a Class E PA uses integration of a drain voltage over a specified integration interval, and the integration result is compared to a threshold value to detect a reactance shift under high inductive load conditions (see e.g. PCT/CN2016/010423).

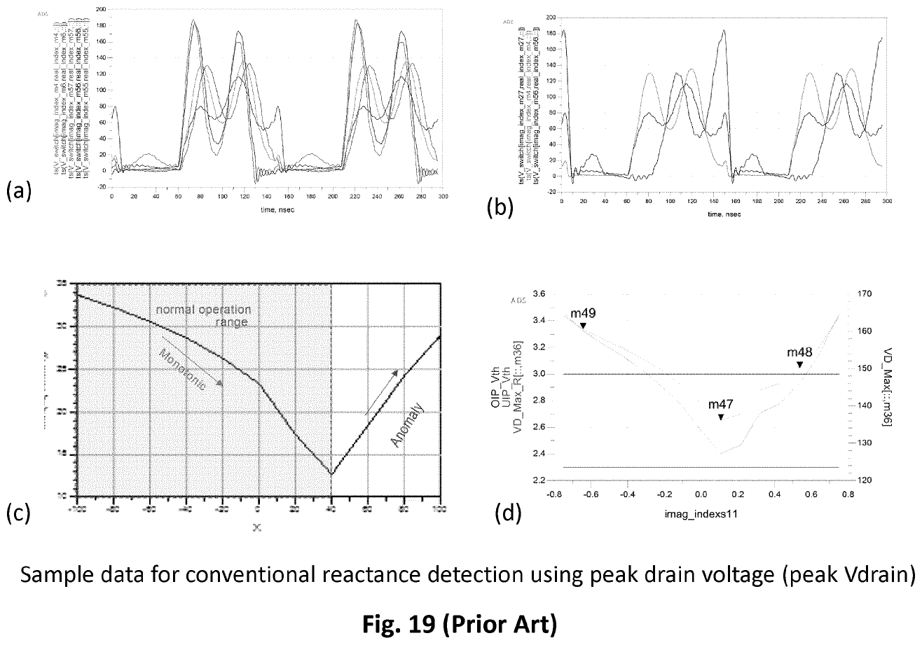

FIG. 19 (Prior Art) shows example data for conventional reactance detection using peak drain voltage (peak Vdrain). In the capacitive region and inductive region, as shown in FIG. 19, ideally in a Class EF2 PA, which has a twin peak drain voltage, the first peak drain voltage is higher than second peak in the capacitance region (FIG. 19 (a)) and the first peak drain voltage is lower than the second in the inductive region (FIG. 19 (b)); also, the ratio of drain peak voltage over Vdd monotonically decreases as reactance (jX) shifts to the inductive region (see FIG. 19 (c) and FIG. 19 (d)). However, in a large inductive region (say X>40), which is outside of normal operation range, peak Vdrain increases with inductance, which creates ambiguity in determining the implied load condition. And a triple peak voltage can occur as well. The peak Vdrain method is applicable only to reactance shift detection for auto-tuning purposes, but cannot be used as a protection mechanism. So, the current known solutions are not effective in protecting against extreme inductive load conditions in a fast and non-ambiguous manner for a Class EF2 PA.

Thus, another aspect of the disclosed inventions provides a real-time hardware implemented method to perform Over Dissipation Protection (ODP), which leverages unique characteristics of constant current Class EF2 amplifier waveforms, and directly measures the physical quantity that is proportional to thermal dissipation on the transistor to allow fast detection and protection against non-ideal inductive loading conditions, particularly for a 3D charging system for charging multiple devices. This method of inductive load and over-dissipation detection/protection takes advantage of a unique Vdrain waveform of a class EF2 power amplifier with EMI filter. This method is potentially faster, simpler to implement and more robust compared to previous known solutions.

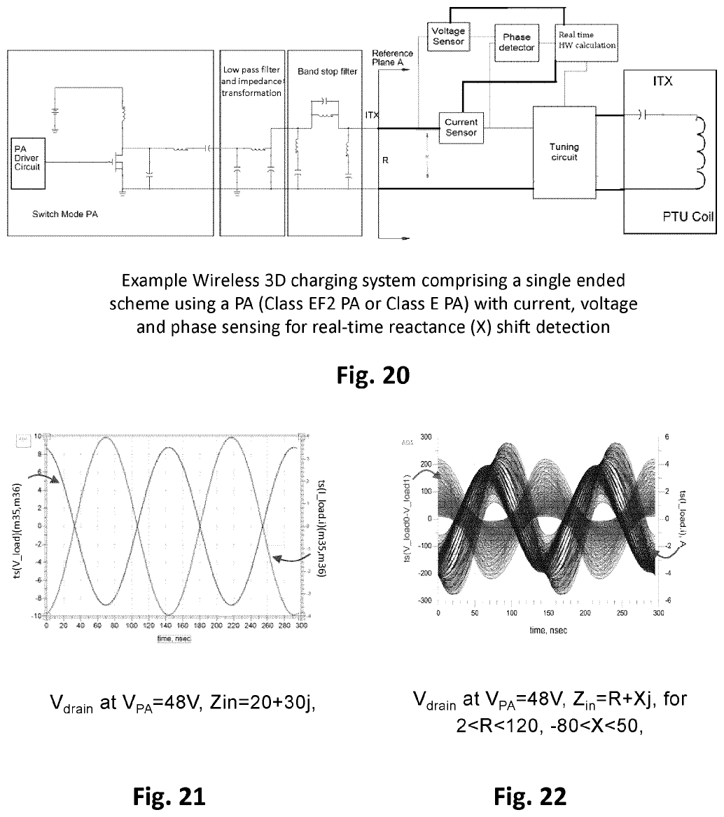

FIG. 20 illustrates an example wireless 3D charging system comprising a single ended scheme using a PA (Class EF2 PA or Class E PA) with current, voltage and phase sensing for real-time reactance (X) shift detection. For a class EF2 power amplifier with EMI filter, as shown in FIG. 20, at optimum efficiency operating point of zero voltage switching (ZVS) and zero voltage differential switching with 35-37% duty cycle, the ideal drain voltage (Vdrain) waveform of the switch mode PA is depicted in FIG. 21.

The reference plane of the impedance detection is set at the output of EMI filter. (reference plane A). As an example, the voltage and current waveform at reference plane A is shown in FIG. 21 for VPA=48V, Zin=(20+30j); and in FIG. 22 for a range of impedance R+Xj, for 2<R<120; −80<X<50. Both the voltage and current waveform at reference plane A are pure sine wave. So, the impedance is easily calculated with very high accuracy by equation (1) above. Also, a real-time hardware trigger circuit can be created using voltage and current detection. A hardware implementation is inherently faster and more robust.

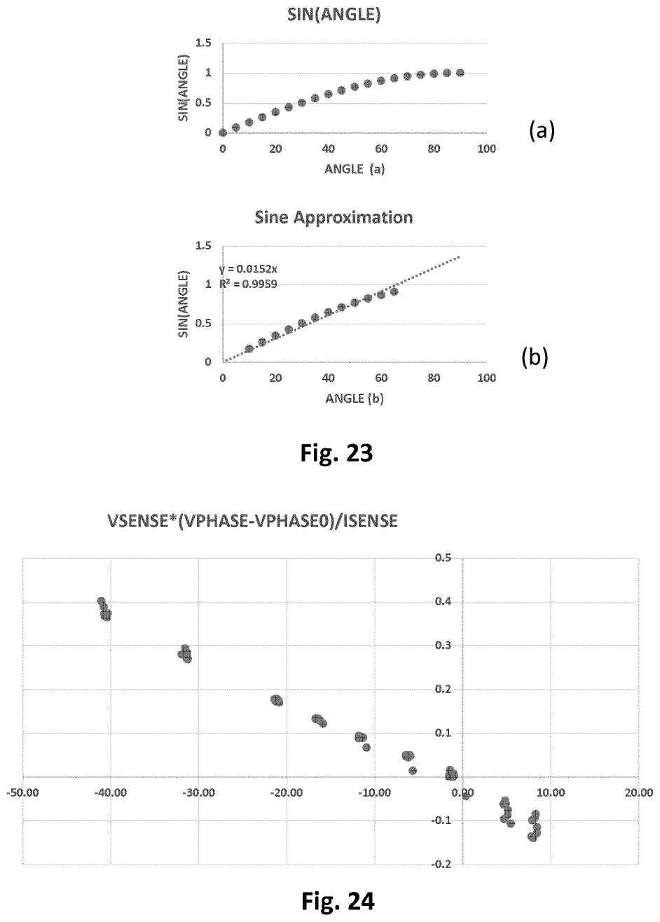

The reactance is rewritten here in another form. The current and voltage are obtained from a voltage sensor and current sensor, and to get from θ to sin θ, with hardware directly, an approximation is implemented for simplification. For example, if the range of angle θ is from 10 to 70 degrees, then sin θ, could be approximated to be linear with θ, and sin θ, could be approximated by a linear fitting function of θ, as illustrated in FIG. 23.

Then simplifying using proportionality assumption here: At X≤−10,))

Vth=VSENSE/ISENSE(VPHASE-VPHASE(0°))≥0.066 (8)

where VPHASE(0)=Vphase0=1.13

The value changes due to the current dependency of the phase detector chip. Both) VPHASE(0°) and the proportionality constant γ changes with I_{TX}.

FIG. 24 depicts the variation of threshold value with I_{TX} (current, in mA), and Vphase0 is linear fitting as below:)

VPHASE(0°)=Vphase0=0.0377*ISENSE+0.932 (9)

Vth=0.073 (10)

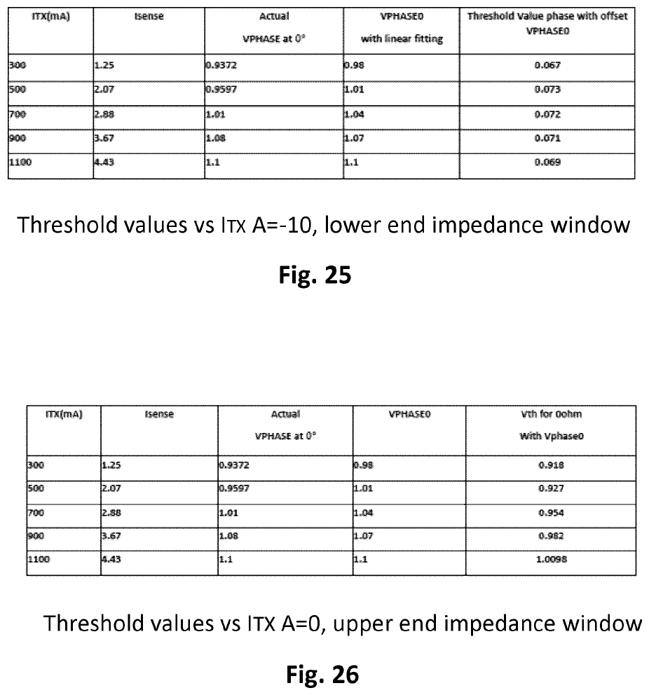

FIG. 25 shows examples of threshold values of vs. I_{Tx} for A=−10, for the lower end of the impedance window. FIG. 26 shows examples of threshold values vs. I_{TX} for A=0, for the upper end of the impedance window.

As an example, equations (8)-(10) are based on A=−10 ohm for the lower impedance window, and A=0 ohm for the upper impedance window, and linear fitting on Vphase0 to get equation (12) from the FIG. 25 and FIG. 26:

Vth=0.918*VPHASE0 (12)

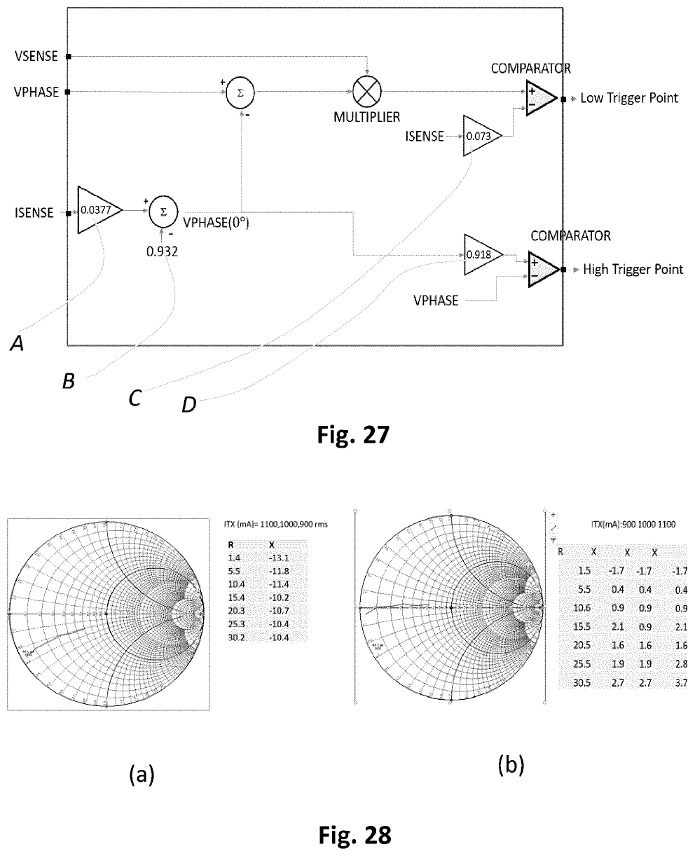

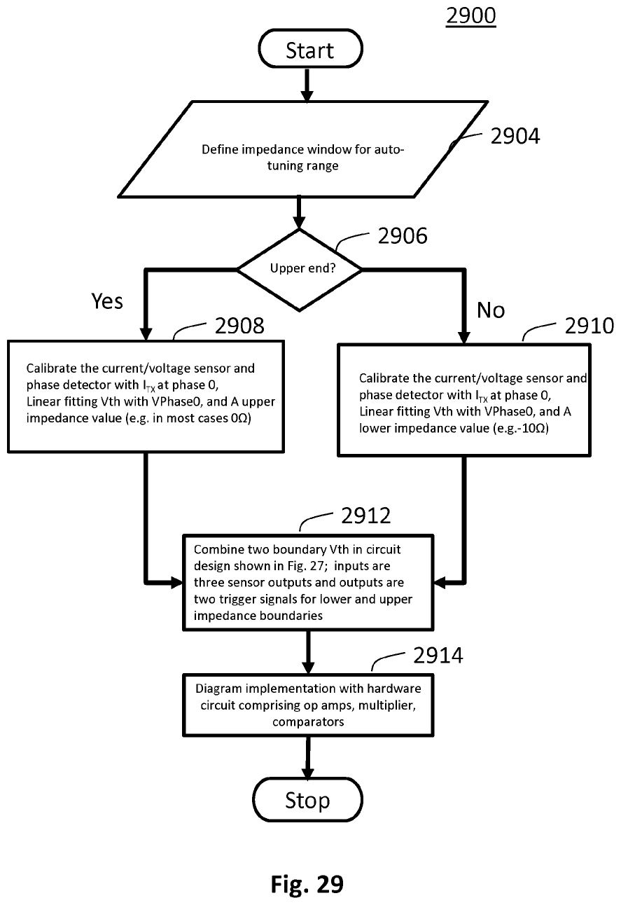

To convert equations (8)-(12), a hardware circuit of an example embodiment is shown in FIG. 27.

Some actual example test data on the circuit is shown in FIG. 28 (a) for a lower end of an impedance window and in FIG. 28 (b) for an upper end of an impedance window.

This design methodology provides for impedance window detection with real-time hardware, which is applicable for over-dissipation protection and for an auto-tuning system. Impedance detection using a real-time hardware circuit allows simple, fast and robust over-dissipation protection and inductive reactance detection for a pre-defined impedance window.

The methodology design flow is shown in FIG. 29, which is a flow chart 2900 for detection of the impedance window. Inputs are received to define the impedance window for auto-tuning range (block 2904), if it is determined that the input is at the upper end (block 2906), then the current/voltage sensor and phase detector are calibrated with I_{TX} at phase 0, linear fitting Vth with VPhase0, and a upper impedance value (e.g. in most cases 0 Ω) (block 2908). If it is determined that the input is not at the upper end (block 2906), then the current/voltage sensor and phase detector are calibrated with I_{TX} at phase 0, linear fitting Vth with VPhase0, and a lower impedance value (e.g. −10 Ω). Then, the two boundary Vth are combined in circuit design (e.g. shown in FIG. 27); inputs are three sensor outputs and outputs are two trigger signals for lower and upper impedance boundaries (block 2912). A hardware circuit is then developed for the detected impedance window (block 2914).

Examples of sensor designs for voltage detection, current detection and phase detection are now described. These are used to detect when a load condition exceeds a certain inductive load threshold value, e.g. to provide a control signal (trigger signal) which can be further applied for auto-tuning control (as described in the following section) or over-dissipation protection.

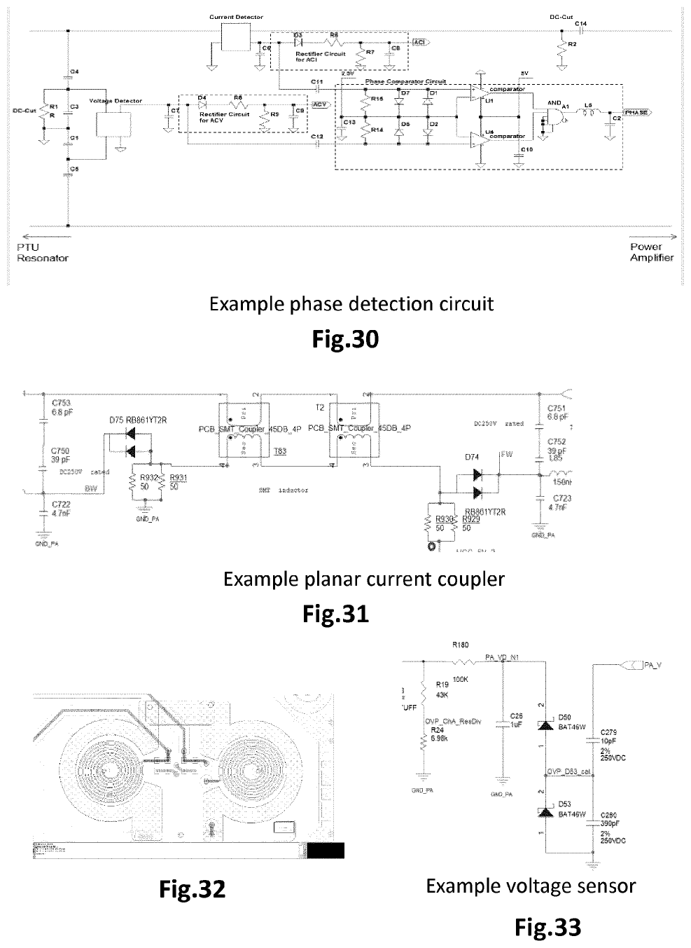

FIG. 30 shows an example of a phase detection circuit design. FIG. 31 shows an example of a planar current coupler circuit design. FIG. 32 shows a CAD drawing of part of a circuit comprising a planar current coupler to show the coil structure; that is the coils are multilayer coils to provide a long coil length for improved coupling, with small coil dimensions, i.e. very small coil area. FIG. 33 shows an example of a voltage sensor circuit design.

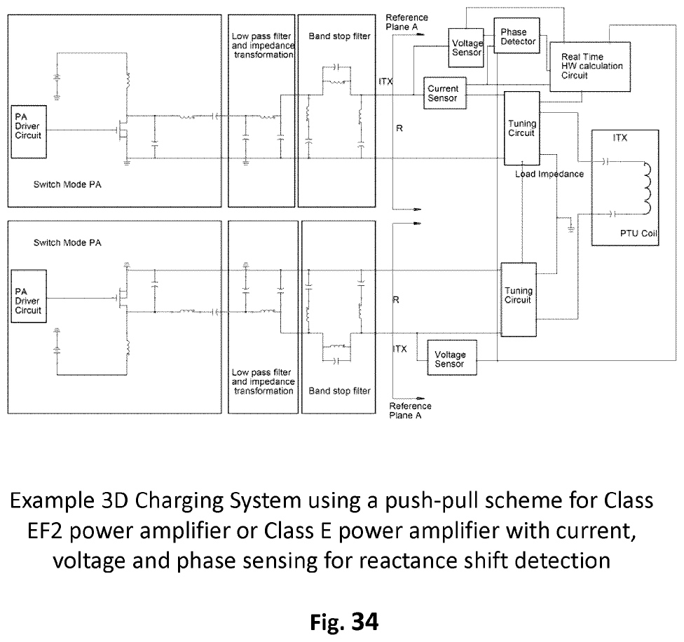

FIG. 34 shows a schematic block diagram of a PTU comprising a circuit for impedance detection of an example embodiment comprising a push-pull scheme for Class EF2 and Class E amplifiers with real-time current, voltage and phase sensing for X detection.

### Auto-Tuning

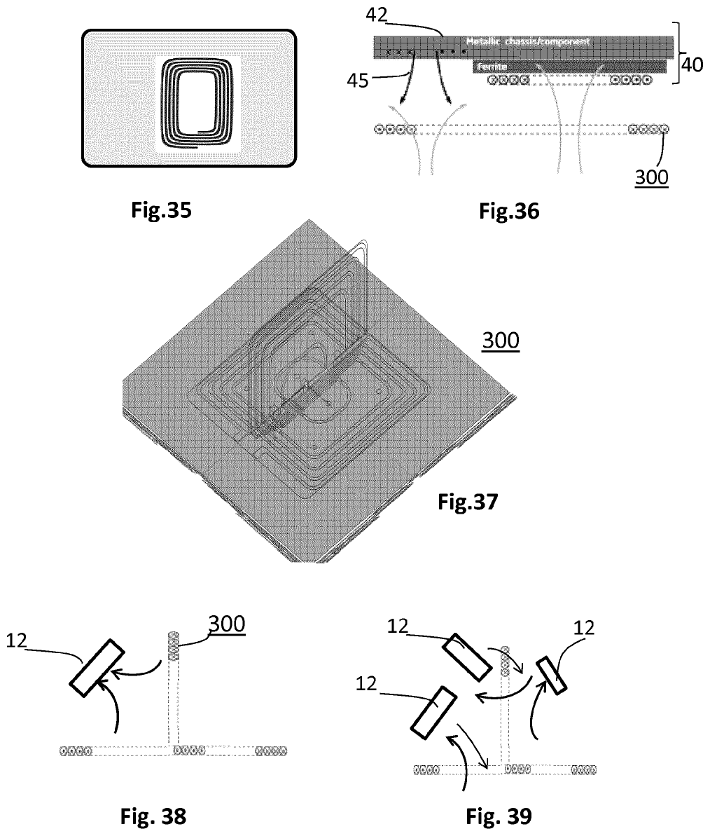

In a 3D charging system, it is a significant challenge to maintain system operation in an optimal efficiency impedance range. Also, in magnetic resonance based wireless charging systems (such as Airfuel), it is important to maintain the power transmitting unit (PTU) coil in resonance. Detuning may occur when a power receiving unit (PRU) is placed in the 3D charging area which is covered by the 3D PTU coil. Small devices, such as small smart phones or wearables (e.g. as shown schematically in FIG. 5 and FIG. 35), in general do not create too much detuning, as the receiver coil and ferrite material in the PRU covers most of the metallic components in the device, which itself is limited in size. As illustrated in the schematic cross-sectional side view of a wireless charging system comprising a 3D coil 300 and a PRU shown in FIG. 36 the metallic chassis 42 of a larger size PRU device 40, such as a tablet PC, may generates some eddy current 45, which detunes the PTU coil.

As systems are developed to push WPT towards higher power for larger devices, such as robots and drones for industrial application, and to provide systems for 3D charging applications for multiple small mobile devices, higher power requirements and the flexibility of larger, 3D charging spaces creates further challenges. The chassis of a tablet PC is significantly larger than that of smartphones and the exposed portion of the chassis and metallic components generate eddy currents in reaction to the charging field applied to it, e.g. as shown schematically in FIG. 36, and significantly reduces the inductance of the PTU coil, which detunes it away from resonance.

FIG. 38 shows a schematic diagram to illustrate a single mobile device 12 positioned in the 3D charging space of the 3D transmitter coil of FIG. 37. When multiple small mobile devices 12 are placed in the 3D charging space of a 3D coil e.g. as illustrated schematically in FIG. 39, this detuning effect significantly changes the PTU operation impedance. This means that, because the power amplifier operates in constant current mode, when there is detuning, it operates in an impedance range which results in lower efficiency operation, and reduces the deliverable power to the resonator coil. Lower efficiency operation of PA will increase dissipation power, which will be converted to heat, and may impact the system reliability and could damage the PA, particularly in high power applications.

A system of an example embodiment for dynamic adaptive tuning for high power wireless charging PTUs will now be described. The basic operating principle is illustrated in

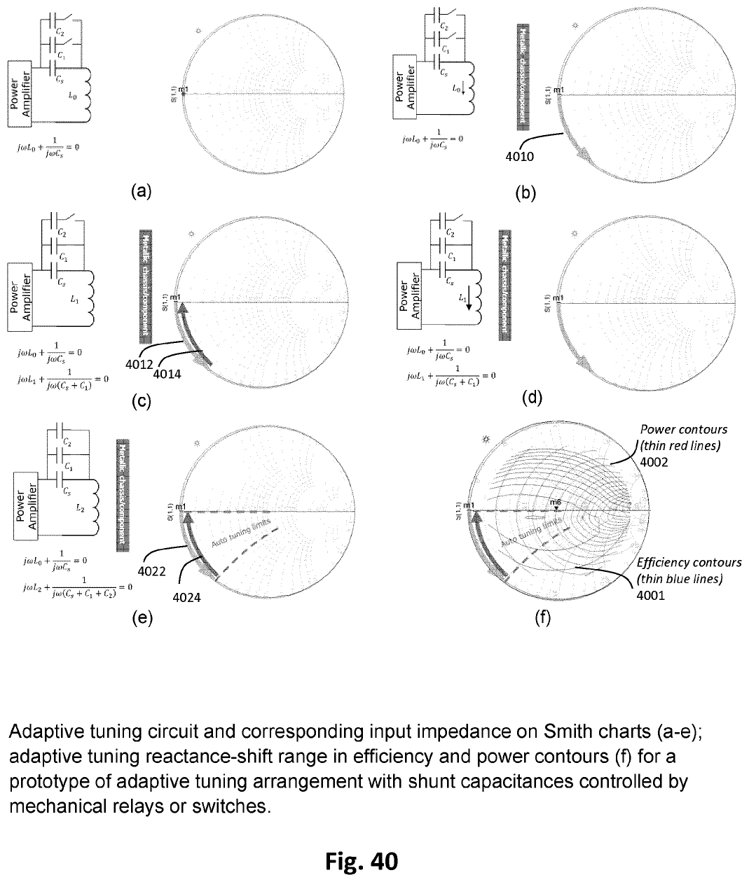

FIG. 40. As shown in FIG. 40 (a), the adaptive tuning circuit consists of a plurality of tuning capacitors (C₁, C₂ . . . Cn) connected in shunt with the main series tuning capacitor (Cₛ). The configuration of each tuning capacitor is controlled by a switch in series to it. When there is no device presented to the PTU coil, the PTU coil is series tuned by the series tuning capacitor (Cₛ). When a device with a large metallic chassis/component is introduced to the PTU coil, as shown in FIG. 40 (b), the inductance of the PTU coil (L₀) reduces 4010, resulting in a reactance shift of the load presented to the Power Amplifier (PA). Once the reactance shift reaches a certain pre-defined threshold, as shown in FIG. 40 (c), the adaptive tuning circuit is triggered to switch in additional tuning capacitance (C₁) such that the combined tuning capacitance (Cₛ+C₁) 4014 resonates with the reduced PTU coil inductance (L₁) 4012.

As more reactance shift is introduced by devices under charge FIG. 40 (d), further reduction in PTU coil inductance results in triggering more tuning capacitance to be switched in, at the same reactance shift threshold, as illustrated in FIG. 40 (e), where the combined tuning capacitance (C₁+C₂+C_{S}) 4024 resonates with the further reduced PTU coil inductance (L₂) 4022. This process is repeated with more bits controlling switching of additional parallel tuning capacitance to compensate for any potential reactance shift that may be caused by one or multiple PRU devices.

As shown in FIG. 40 (f), this adaptive tuning arrangement with a plurality of switchable shunt capacitors confines the reactance shift presented to the PA to a small range, within which, the output power (red contours 4002) and high efficiency (blue contours 4001) of the PA can be maintained in a required range. Although effective, the configuration shown in FIG. 40 with tuning capacitance added in shunt has several limitations, e.g. non-uniform reactance compensation step size, and limited overall range.

As shown schematically in FIG. 40 (f), an ideal configuration of an adaptive tuning circuit should always be able to bring the coil back to resonance, once a specific fixed reactance shift limit is reached, i.e. by triggering the adaptive tuning circuit to switch to the next tuning state. However, a circuit topology comprising tuning capacitances added in shunt, as illustrated in FIG. 40, can meet this condition only in a few state transitions. More specifically, only when a new tuning capacitor is introduced (say states 1, 2, 4, 8) can such a resonance condition can be met. During other state transitions, the combination of the capacitance always introduces less compensation than needed to bring the circuit to resonance. As a result, the total range of the reactance compensation that can be offered by this topology is far less than a theoretical optimum.

### Combination of Rough-Tuning and Fine-Tuning With Uniform Step Size and Large Total Reactance Shift Compensation Range

A 3D charging system for multiple mobile devices needs a greater impedance range, to accommodate more flexible positioning of each device in the 3D charging space. To address this challenge, an adaptive tuning circuit configuration of another example embodiment is proposed, which improves the impedance tuning range, step size and reliability of the adaptive tuning circuitry.

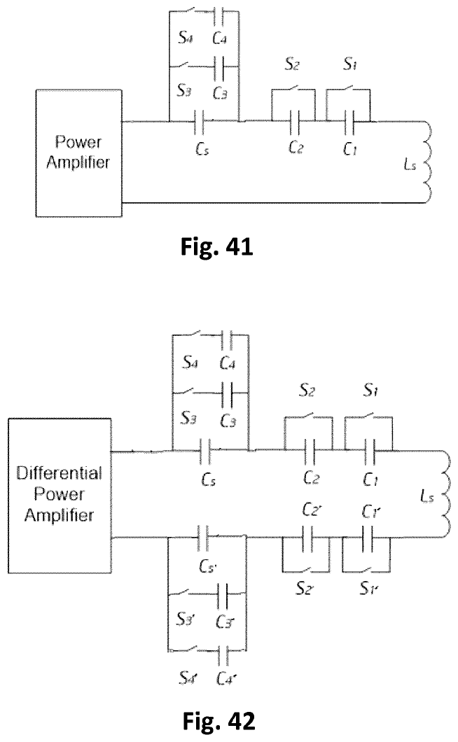

An adaptive tuning circuit topology of an example embodiment with 4 switchable tuning capacitors is shown in FIG. 41. There is a series capacitor Cs, which is an initial starting capacitor. The tuning capacitors are in two groups: all capacitors in group one are connected in series and switches (S₁, S₂) are connected in parallel with the tuning capacitors (e.g. C₂, C₁), which is the fine-tuning group, and all capacitors in group two are connected in parallel and switches (S₃, S₄) are in series with these tuning capacitors (e.g. C₄, C₃), which is the rough-tuning group. When the coil is exhibiting highest inductance (i.e. open pad condition, all mobile devices are close to coil), all tuning capacitors are connected in series (e.g. switch state S₁S₂S₃S₄=0011, S₁,S₂ for fine-tuning, S₃,S₄ for rough tuning, to generate the highest tuning reactance. As devices are introduced to the PTU coil, the inductance Ls reduces, accordingly, the switches are configured to open the combination of rough tuning capacitors, to achieve the maximum impedance coverage with minimum capacitors; and the fine-tuning switches are configured to short-out the combination of series tuning capacitors to achieve a lower reactance to tune the circuit to near resonance; this arrangement provides a uniform smaller step size for impedance optimization efficiency tuning, and reduces the number of capacitors in series configuration, therefore minimizing the capacitor loss of the tuning circuit.

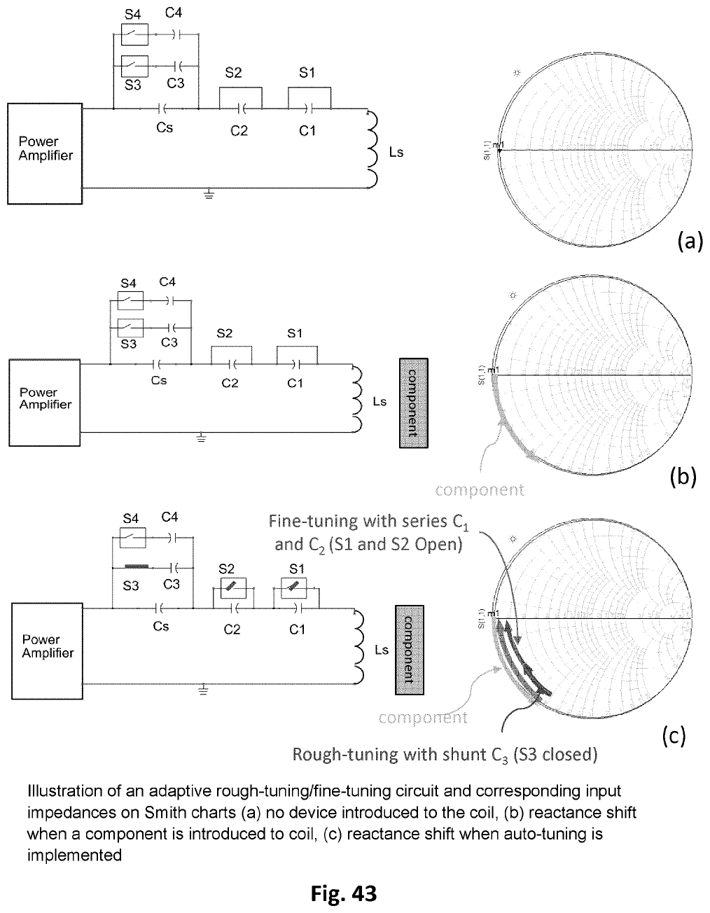

FIG. 42 shows a tuning capacitor arrangement of another example embodiment, configured for a push-pull circuit topology. In other example embodiments (not illustrated in the drawings), the tuning capacitor arrangement may comprise more than two fine-tuning capacitors and more than two rough-tuning capacitors, and/or different numbers of fine-tuning and rough-tuning capacitors. However, if the number of tuning sections is increased, as explained below, this would impact the system efficiency, due to the increased capacitor losses.

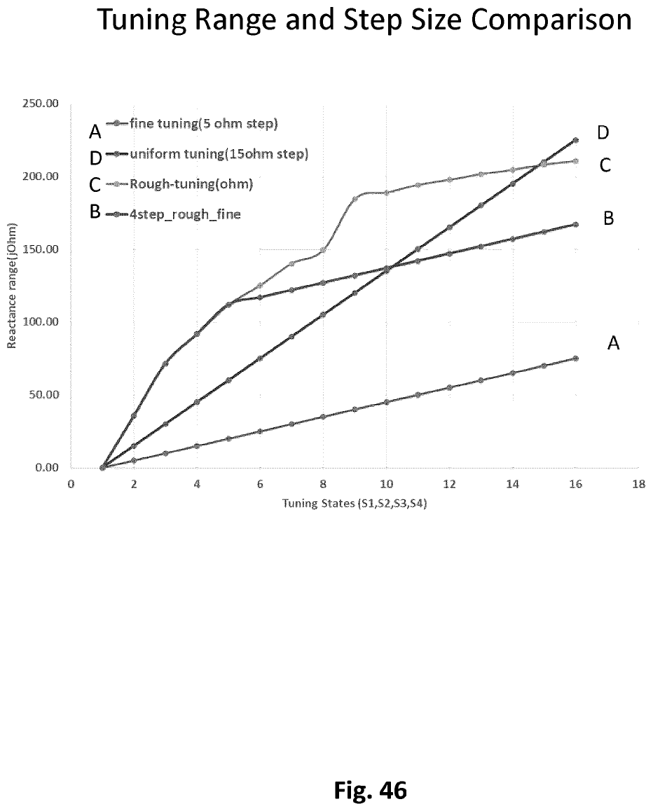

As an example, FIG. 46 shows some plots which depicts an operational principle of both rough-tuning and fine-tuning.

FIG. 43 shows some example switching states and Smith diagrams to illustrate rough-tuning and fine-tuning. In view (a) there is no device introduced to the coil, and only the initial starting capacitor Cs is connected. View (b) illustrates the reactance shift when a component introduced to the coil. View (c) illustrates the reactance shift when auto-tuning is implemented comprising shunt capacitor C₃ for rough-tuning and series capacitors C₁ and C₂ for fine tuning.

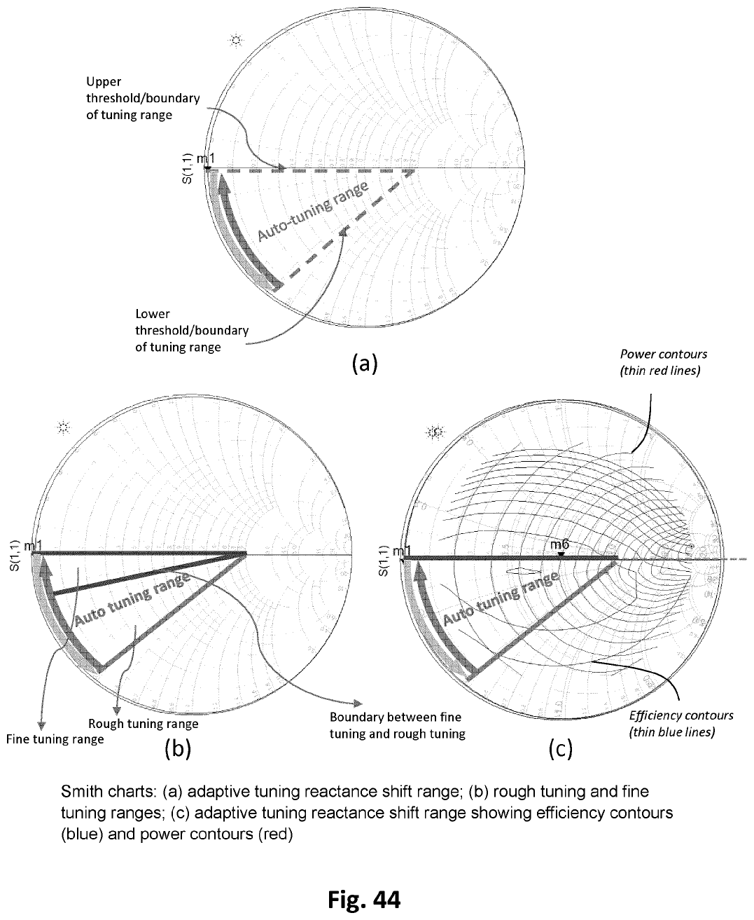

FIG. 44 shows example Smith charts (a), (b) and (c) to illustrate the reactance shift range for adaptive tuning of reactance with fine and rough tuning, wherein rough-tuning covers a larger impedance area with bigger step size and fine-tuning covers a smaller impedance area with smaller uniform step sizes. View (a) illustrates the upper and lower thresholds or boundaries of the tuning range. View (b) illustrates the rough tuning range and the fine tuning range, and the boundary between fine tuning and rough tuning. View (c) illustrates the adaptive tuning reactance shift range and shows efficiency contours and power contours.

In the fine-tuning section, the capacitor values are selected so that the fine-tuning step size of reactance is uniform. In order to ensure uniform stepping between tuning configurations and a maximum total fine-tuning range, a relationship of the fine-tuning capacitance values need to be maintained as follows, where n is the maximum number of capacitors in the fine-tuning section:

$${C}_{1} = \frac{{C}_{2}}{2} = \frac{{C}_{3}}{4} = \frac{{C}_{i}}{{2}^{i - 1}} = {C}_{t} , i = 1 , 2 , … n$$

In this case, the total reactance created by the adaptive fine-tuning circuit can be written as:

$${X}_{C} ( {s}_{1} {s}_{2} … {s}_{n} ) = - \frac{j}{ω} ( \frac{\overline{{s}_{1}}}{{C}_{1}} + \frac{\overline{{s}_{2}}}{{C}_{2}} + … \frac{{\overline{s}}_{n}}{C n} )$$

$${X}_{c} ( {s}_{1} , {s}_{2} … {s}_{n} ) = - \frac{j}{w} ( \frac{{2}^{n - 1} \overline{{s}_{1}} + {2}^{n - 2} \overline{{s}_{2}} + … \overline{{s}_{n}}}{{2}^{n - 1} ct} )$$

where the Sₙ is a binary number indicating the switch state of each switch, Sᵢ=1 represents closed state of the switch; Sᵢ=0 represents open state of the switch. As can be seen, between adjacent switch states (say S₁S₂ and S₁S₂+1), the reactance difference introduced by the adaptive fine-tuning network is always the same value: 1/(jω2ⁿ⁻¹Cₜ) Ohm. n is the maximum number of capacitors in the fine-tuning section, and the total number of fine-tuning steps is (2ⁿ−1).

In the rough-tuning section, the rough-tuning step size of reactance is almost uniform, in order to ensure uniform stepping in the first few steps of the rough-tuning range, a relationship of the rough-tuning capacitance values needs to be maintained as follows, where m-n is the maximum number of capacitors in the rough-tuning section:

$${C}_{n + 1} = \frac{{c}_{n + 2}}{2} = \frac{{c}_{n + 3}}{4} = \frac{{c}_{j}}{{2}^{j - 1}} = {C}_{p} , j = n + 1 , n + 2 … m$$

$${X}_{C} ( {S}_{1} {S}_{2} … {S}_{m} ) = - \frac{j}{ω} ( \frac{1}{{C}_{S} + {C}_{n + 1} \cdot {\overline{s}}_{n + 1} + {C}_{n + 2} \cdot {\overline{s}}_{n + 2} + {C}_{m} \cdot {\overline{s}}_{m}} )$$

where Sₙ is a binary number indicating the switch state of each switch, Sᵢ=1 represents closed state of the switch; Sᵢ=0 represents open state of the switch. As can be seen, between adjacent switch states (say S₁S₂ and S₁S₂+1), the reactance difference introduced by the adaptive rough-tuning network is almost the same value: 1/(jω2^{j-1}Cₚ) Ohm, when the Cs is large than 2^{j-1}Cₚ. m-n is the maximum number of capacitors in the rough-tuning section, and the total number of rough-tuning steps is (2^{m-n-}1).

This combination solution of the rough-tuning and fine-tuning solution reduces the total number of series capacitors, further improving the efficiency. Also, this capacitor arrangement extends the tuning range with large tuning steps for rough-tuning, and more accurate fine-tuning steps in the high efficiency impedance range.

For a fixed maximum step size (i.e. maximum change between adjacent tuning states), this adaptive rough-tuning circuit configuration allows for a maximum reactance shift compensation range for given number of switches. Alternatively, for the same total reactance shift compensation range Xcₜₒₜₐₗ required, a minimum step size can be achieved with this fine-tuning circuit topology, where the minimum step size is Xc_{total/(}2ⁿ−1) in the fine tuning section. The total reactance shift compensation range is given as:

$${X}_{C} ( {s}_{1} , {s}_{2} … {s}_{n} , {s}_{n + 1} , {s}_{n + 2} , … , {s}_{m} ) = - \frac{j}{ω} ( \frac{1}{{C}_{s} + {C}_{n + 1} \cdot {\overline{s}}_{n + 1} + {C}_{n + 2} \cdot {\overline{s}}_{n + 2} + … + {C}_{m} \cdot {\overline{s}}_{m}} + \frac{{2}^{n - 1} \overline{{s}_{1}} + {2}^{n - 2} \overline{{s}_{2}} + … \overline{{s}_{n}}}{{2}^{n - 1} {C}_{t}} )$$

### Implementation of Adaptive Reactance Tuning in Push-Pull Configuration

A push-pull PA configuration is frequently used in high power designs, particularly for WPT applications. The push-pull adaptive tuning reactance shift compensation circuitry can be implemented in push-pull PA design as shown in FIG. 42. The reactance shift compensation is done by switching the corresponding tuning capacitors on both upper and lower side chains at the same time.

In the push-pull configuration of adaptive tuning network following the proposed capacitance arrangement, the total reactance created by the adaptive tuning circuit can be written as:

For example, for the capacitor arrangement shown in FIG. 42:

$${X}_{C} ( {s}_{1} , {s}_{2} , {s}_{3} , {s}_{4} , {s}_{1}^{′} , {s}_{2}^{′} , {s}_{3}^{′} , {s}_{4}^{′} ) = - \frac{j}{ω} ( \frac{1}{{C}_{s} + {C}_{1} \cdot {\overline{s}}_{1} + {C}_{2} \cdot {\overline{s}}_{2} + {C}_{3} \cdot {\overline{s}}_{3} + {C}_{4} \cdot {\overline{s}}_{4}} + \frac{1}{{C}_{s}^{′} + {C}_{1}^{′} \cdot {\overline{s}}_{1}^{′} + {C}_{2}^{′} \cdot {\overline{s}}_{2}^{′} + {C}_{3}^{′} \cdot {\overline{s}}_{3}^{′} + {C}_{4}^{′} \cdot {\overline{s}}_{4}^{′}} + \frac{{2}^{n - 1} ( \overline{{s}_{1}} + \overline{{s}_{1}^{′}} ) + {2}^{n - 2} ( \overline{{s}_{2} + \overline{{s}_{2}^{′}}} ) + … \overline{{s}_{n}}}{{2}^{n} {C}_{t}} )$$

For any number of switches:

$${X}_{C} ( {s}_{1} , {s}_{2} … {s}_{n} , {s}_{n + 1} , {s}_{n + 2} , … , {s}_{m} , {s}_{1}^{′} , {s}_{2}^{′} … {s}_{n}^{′} , {s}_{n + 1}^{′} , {s}_{n + 2}^{′} , … , {s}_{m}^{′} ) = - \frac{j}{ω} ( \frac{1}{{C}_{s} + {C}_{n + 1} \cdot {\overline{s}}_{n + 1} + {C}_{n + 2} \cdot {\overline{s}}_{n + 2} + … + {C}_{m} \cdot {\overline{s}}_{m}} + \frac{1}{{C}_{s}^{′} + {C}_{n + 1} \cdot {\overline{s}}_{n + 1}^{′} + {C}_{n + 2} \cdot {\overline{s}}_{n + 2}^{′} + … + {C}_{m} \cdot {\overline{s}}_{m}^{′}} + \frac{{2}^{n - 1} ( \overline{{s}_{1}} + \overline{{s}_{1}^{′}} ) + {2}^{n - 2} ( \overline{{s}_{2} + \overline{{s}_{2}^{′}}} ) + … \overline{{s}_{n}}}{{2}^{n} {C}_{t}} )$$

In this case, as illustrated in FIG. 42, if the two sides are switched asynchronously and limit the difference to one step (i.e. |S₁S₂S₃S₄−S₁′S₂′S₃′S₄′|≤1), the minimum change in reactance shift compensation offered by the adaptive tuning network can be reduced to: 1/(jω2ⁿCₜ), i.e. half the step size of the single ended adaptive tuning network. A finer step size offers tighter control of the PA performance for improved PA efficiency.

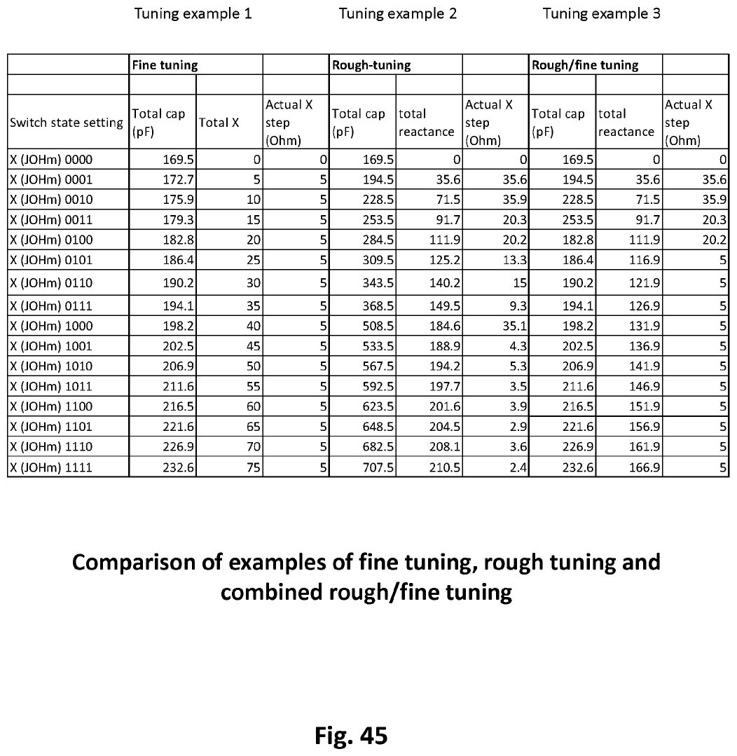

The table in FIG. 45 shows a comparison of the adaptive tuning reactance compensation between the shunt configuration shown in FIG. 40 and the topology of the embodiments shown in FIGS. 41, 42 and 43, at each switch state S₁S₂S₃S₄ (expressed in decimal format of the binary number). As can be seen, that given the limitation of the conventional adaptive tuning topology with single tuning mode, the maximum step size is only achievable when a bigger step size is involved (i.e. from stage transition from 0 to 1, 1 to 2, 3 to 4 and 7 to 8 shown in the table in FIG. 45). Smaller, more accurate steps are required for a 3D charging system, which means that the maximum tuning range would be limited, unless the number of tuning sections is increased. However, this would impact the system efficiency, i.e. due to the increased capacitor losses. On the other hand, the circuit topology disclosed herein with a rough tuning/fine tuning capacitance configuration ensures a consistent maximum step size as the tuning state increases, and covers a much larger total compensation range compared to a conventional configuration, and at the same time, maintains accurate tuning with a smaller fine-tuning step size. For implementation, the rough-tuning step size is designed to cover the full range required, and each rough-tuning action will run fine-tuning to make sure the tuning step is optimized. In a design example, the fine-tuning step size is 5 ohm, and rough-tuning step size is in a range of 35 ohm to 20 ohm, with non-uniform step size. The fine-tuning is the provided by the topology pattern of series tuning capacitors, to cover a smaller range with small uniform step size; and the rough tuning is provided by the topology pattern of parallel tuning capacitors.

FIG. 46 shows some plots which depict some examples of both rough-tuning and fine-tuning.

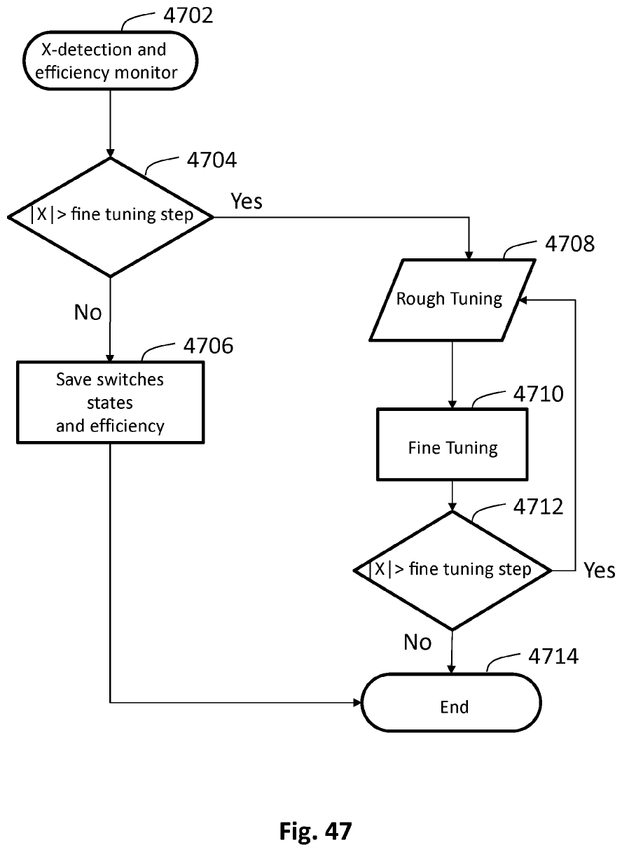

FIG. 47 shows a flow chart for a method of how the firmware determines and controls the rough/fine tuning, i.e. when to add a half step to the relay state. The firmware detects the load reactance every t₀ time interval (block 4702). If the reactance shift is larger than half of the designed step size (block 4704), one side of the relay will add one step (e.g. rough tuning) (block 4708). Since the step is only applied to one side, the overall reactance shift caused from this action is only half of the step size. Then the firmware does the reactance detection again to make sure the reactance shift is within a half of the step size (block 4712). In some embodiments, the process may perform a fine tuning step (block 4710) after the rough tuning (block 4708). If the reactance shift is not larger than half of the designed step size (block 4704), then the current switches states are maintained (block 4706) and the process ends (block 4714).

The table in FIG. 45 shows 4-bit reactance shift compensation step sizes for a fine-tuning capacitor topology, a rough tuning capacitor topology and the rough/fine tuning combination. They are designed to tune the same PTU coil with the same maximum step size. From the rough tuning columns in the Table in FIG. 45, once switches states setting 0001, 0010, 0100, and 1000 are set, all other switch states are dependent on above 4 states and set. Only the above 4 states have the same reactance step, while others are smaller. As a result, the total reactance shift is only j134 Ohm. From the series tuning, fine tuning columns in the Table in FIG. 45, fine-tuning, as long as the tuning capacitors, from MSB (most significant bit) to LSB (least significant bit), have a ratio of 1:2:4:8 (e.g. 1173pF, 2347pF, 4694pF and 9488pF respectively), not all of them are used in the design for fine tuning, that will depend on the maximum impedance range. For example, 339pF, 115pF, 59pF and 25p F are used for rough tuning respectively, and all tuning steps are the same. The uniform step size also results in a much larger total reactance shift range of j167 Ohm. A series tuning capacitor topology can cover more reactance shift with the same number of bits.

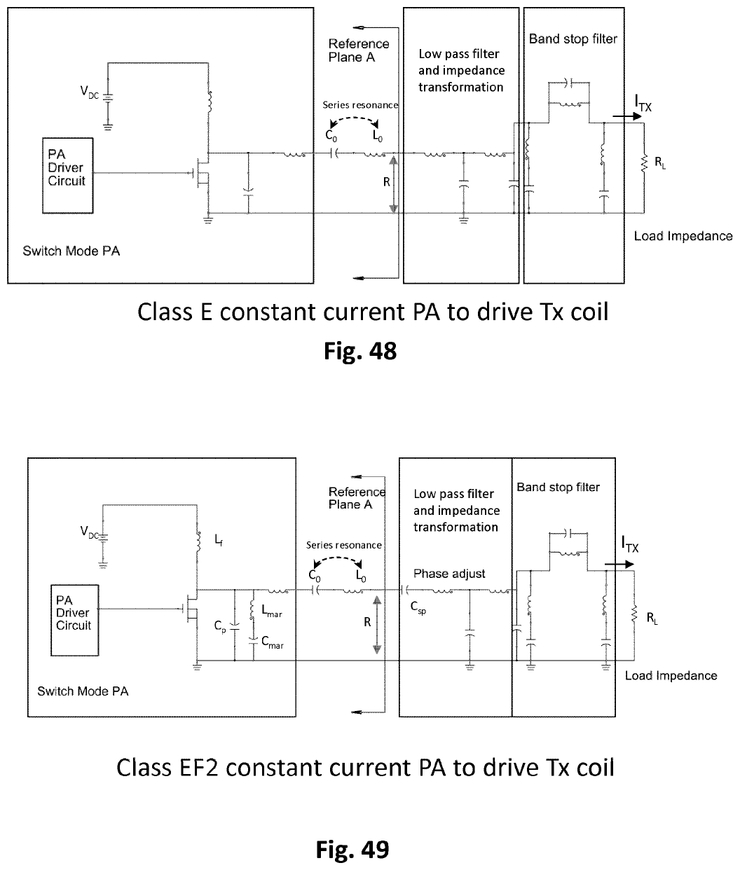

A schematic diagram to illustrate an example class E constant current power amplifier (PA) to drive a transmitter is shown in FIG. 48. A schematic diagram to illustrate an example class EF2 constant current power amplifier (PA) to drive a transmitter is shown in FIG. 49.

Example embodiments of devices, systems and methods for 3D charging comprising 3D coils, X-detection, and auto-tuning have been described in detail. These may be implemented independently or in combination.

Although embodiments of the inventions have been described and illustrated in detail, it is to be clearly understood that the same is by way of illustration and example only and not to be taken by way of limitation, the scope of the present invention being limited only by the appended claims.

1. A resonator coil for generating a magnetic field distribution for a transmitter of an inductive wireless power transfer (WPT) system, comprising:
conductive traces patterned to define a coil topology comprising a plurality of turns, having first and second feed ports;
each turn comprising a first part wherein said conductive traces are defined in a first plane, and a second part wherein said conductive traces are defined in a second plane, wherein the turns of the first and second parts are serially interconnected.

2. The resonator coil of claim 1, wherein the first plane and the second plane are substantially orthogonal.

3. The resonator coil of claim 1, wherein the first plane and the second plane are orthogonal.

4. The resonator coil of any one of claims 1 to 3, wherein the coil topology is configured to generate a three-dimensional (3D) magnetic field distribution for wireless charging within a 3D charging space.

5. The resonator coil of any one of claims 1 to 4, wherein the coil topology is configured to generate a three-dimensional magnetic field distribution for wireless charging within a hemispherical charging space.

6. The resonator coil of any one of claims 1 to 5, wherein the first plane comprises an xy plane, and the second plane comprises a xz plane or a yz plane.

7. The resonator coil of any one of claims 1 to 6, wherein the first plane comprises an xy plane, and the second plane comprises a xz plane, and the charging space comprises a first half and a second half on opposite sides of the xz plane.

8. The resonator coil of any one of claims 1 to 7, wherein trace widths and trace spacings of each turn are configured to optimize a uniformity of the magnetic field distribution within the charging space.

9. The resonator coil of any one of claims 1 to 8 comprising:
a dielectric substrate having a first part that extends in the first plane and a second part that extends in the second plane; and
wherein said first parts of the conductive traces are supported by the first part of the dielectric substrate and the said second parts of the conductive traces are supported by the second part of the dielectric substrate.

10. A 3D resonant wireless charging system comprising:
the resonator coil of any one of claims 1 to 9;
a push-pull Class E power amplifier (PA) or a class EF2 PA; and
a control system configured to enable control of current direction supplied to the coil responsive to a load condition.

11. A 3D resonant wireless charging system comprising:
a resonator coil having a coil topology configured to generate a three-dimensional (3D) magnetic field distribution for wireless charging within a 3D charging space;
a push-pull Class E power amplifier (PA) or a class EF2 PA; and
a control system configured to enable control of current direction responsive to a load condition.

12. The 3D resonant wireless charging system of claim 11, wherein the control system is configured to enable control of at least one of a time interval and a phase of current flow on each part of the coil responsive to said load condition.

13. A reactance (X) shift detection circuit for a 3D resonant inductive wireless charging system comprising:
electronic circuitry comprising:
a first input for receiving a first signal from a voltage sensor,
a second input for receiving a second signal from a current sensor, and
a third input for receiving a third signal from a phase detector;
a first output for outputting a low reactance trigger signal; and
a second output for outputting a high reactance trigger signal;
the electronic circuitry comprising hardware configured for processing said first, second and third signals to provide a real-time computation of a computed reactance value; and
comprising comparator circuitry for comparing said computed reactance value to stored reference values comprising an upper value of a reactance window and lower value of a reactance window; and
if the said reactance value is greater than the upper value, generating and outputting a high reactance trigger signal; or if the said reactance value is less than the lower value, generating and outputting a high reactance trigger signal.

14. The reactance shift detection circuit of claim 13, wherein the upper value of the reactance window and lower value of the reactance window are selected to generate said trigger signals for auto-tuning of reactance.

15. The reactance shift detection circuit of claim 13, wherein the upper value of the reactance window and lower value of the reactance window are selected to generate said trigger signals to implement over-voltage and over-current protection.

16. The reactance shift detection circuit of any one of claims 13 to 15, comprising a phase detection circuit.

17. The reactance shift detection circuit of any one of claims 13 to 15, comprising a current sensing circuit.

18. The reactance shift detection circuit of claim 17 wherein the current sensing circuit comprises a planar current coupler.

19. The reactance shift detection circuit of any one of claims 13 to 15, comprising a voltage sensing circuit.

20. The reactance shift detection circuit of any one of claims 13 to 19, wherein said hardware is configured to compute a threshold voltage based on VSENSE*(VPHASE-VPHASE0)/ISENSE.

21. A 3D resonant inductive wireless charging system comprising:
a power amplifier (PA), wherein the PA comprises a Class E or Class EF2 amplifier with current, voltage and phase sensing for real-time impedance detection comprising the reactance shift detection circuit of any one of claims 13 to 20.

22. The 3D resonant inductive wireless charging system of claim 21, wherein the power amplifier (PA) comprises a Class E or Class EF2 amplifier comprising a push-pull topology.

23. The 3D resonant inductive wireless charging system of claim 21, wherein the power amplifier (PA) comprises a Class E or Class EF2 amplifier comprising a single-ended topology.

24. A circuit for load-adaptive auto-tuning of a power transmitter of a resonant inductive power transfer system, the circuit comprising a tuning capacitor arrangement connected between an input for receiving current from a power amplifier and an output for driving a Tx resonator coil, the capacitor arrangement comprising:
a first series tuning capacitor;
a plurality of switchably connected parallel shunt capacitors connected in parallel with the first series tuning capacitor, each of said plurality of switchably connected parallel capacitors having a series connected switch; and
a plurality of series capacitors that are switchably connected in series, each series capacitor having a parallel connected switch; and
switch states of each switch being configurable to selectively connect or disconnect one or more of said parallel and series capacitors.

25. The circuit of claim 24, wherein values of shunt capacitors are selected to provide coarse tuning steps and values of series capacitors selected to provide fine tuning steps smaller than the coarse tuning steps over a required reactance range.

26. The circuit of any one of claims 24 and 25, wherein values of shunt capacitors are selected to provide coarse tuning steps having uniform or non-uniform step sizes.

27. The circuit of claim 26, wherein values of shunt capacitors are selected to provide coarse tuning steps in a range of about 20 ω to 35 ω.

28. The circuit of any one of claims 24 to 27, wherein values of series capacitors are selected to provide uniform fine-tuning steps.

29. The circuit of any one of claims 24 to 28, wherein values of series capacitors are selected to provide uniform fine-tuning steps of about 5 ω.

30. The circuit of any one of claims 24 to 29, wherein values of parallel and series capacitors are calculated to define tuning step sizes.

31. The circuit of any one of claims 24 to 30, comprising a controller for receiving a trigger signal indicative of a reactance shift, and configuring switches for switchably connecting one or more of said parallel connected capacitors and/or one of more of said series capacitors to provide a required reactance.

32. The circuit of any one of claims 24 to 30 comprising a controller for receiving a trigger signal indicative of a reactance shift, and configuring switches for switchably connecting one or more of said parallel connected capacitors and/or one of more of said series capacitors to provide configure a switch state to provide one of: rough tuning steps, fine tuning steps, and a combination of rough tuning steps and fine tuning steps to provide a required reactance.

33. The circuit of any one of claims 24 to 32, further comprising protection switch means configured for triggering over-voltage protection or over-current protection responsive trigger signals indicative of one of a high impedance boundary value and a low impedance boundary value generated by the reactance shift detection circuit of any one of claims 13 to 20.

34. The circuit of any one of claims 24 to 33 configured for operation with a power amplifier (PA) with push-pull topology.

35. The circuit of any one of claims 24 to 33 configured for operation with a power amplifier (PA) with a single ended topology.

36. A wireless power transfer (WPT) system comprising:
a resonator coil for generating a 3D magnetic field distribution for wireless charging within a 3D charging space;
a power amplifier (PA);
an impedance matching network; and
a control system comprising at least one of:
a) a circuit to control current direction of a push-pull PA in response to a load condition;
b) a reactance-shift (X-shift) detection circuit for triggering at least one of auto-tuning of reactance, over-voltage protection, and over-current protection; and
c) a circuit for load-adaptive auto-tuning of reactance.

37. The wireless power transfer (WPT) system of claim 36, wherein the resonator coil comprises:
conductive traces patterned to define a coil topology comprising a plurality of turns, having first and second feed ports;
each turn comprising a first part wherein said conductive traces are defined in a first plane, and a second part wherein said conductive traces are defined in a second plane,
wherein the turns of the first and second parts are interconnected.

38. The wireless power transfer (WPT) system of claim 36, wherein the circuit to control current direction of push-pull PA in response to a load condition is configured to enable control of at least one of a time interval and a phase of current flow on each part of the coil responsive to said load condition.

39. The wireless power transfer (WPT) system of claim 36, wherein the reactance (X) shift detection circuit comprises:
electronic circuitry comprising:
a first input for receiving a first signal from a voltage sensor,
a second input for receiving a second signal from a current sensor, and
a third input for receiving a third signal from a phase detector;
a first output for outputting a low reactance trigger signal; and
a second output for outputting a high reactance trigger signal;
the electronic circuitry comprising hardware configured for processing said first, second and third signals to provide a real-time computation of a computed reactance value; and
comprising comparator circuitry for comparing said computed reactance value to stored reference values comprising an upper value of a reactance window and lower value of a reactance window;
and
if the said reactance value is greater than the upper value, generating and outputting a high reactance trigger signal; or
if the said reactance value is less than the lower value, generating and outputting a high reactance trigger signal.

40. The wireless power transfer (WPT) system of claim 36, wherein the circuit for load-adaptive auto-tuning of reactance comprises a tuning capacitor arrangement connected between an input for receiving current from a power amplifier and an output for driving a Tx resonator coil, the capacitor arrangement comprising:
a first series tuning capacitor;
a plurality of switchably connected parallel shunt capacitors connected in parallel with the first series tuning capacitor, each of said plurality of switchably connected parallel capacitors having a series connected switch; and
a plurality of series capacitors that are switchably connected in series, each series capacitor having a parallel connected switch; and
switch states of each switch being configurable to selectively connect or disconnect one or more of said parallel and series capacitors.
